(19) United States
(12) Patent Application Publication
(10) Pub. No.: US 2007/0044906 A1
(43) Pub. Date: Mar. 1, 2007

(54) Multilayer polymeric composites having a layer of dispersed fluoroelastomer in thermoplastic

(75) Inventor: Edward Hosung Park, Saline, MI (US)

Correspondence Address: FREUDENBERG-NOK GENERAL PARTNERSHIP;LEGAL DEPARTMENT, 47690 EAST ANCHOR COURT, PLYMOUTH, MI, 48170-2455, US

(73) Assignee: Freudenberg-NOK General Partnership, Plymouth, MI (US)

(21) Appl. No.: 11/216,710

(22) Filed: Aug. 31, 2005

(51) Int. Cl. B32B 27/00; B32B 3/02; B29C 47/06; H01J 37/30

(52) U.S. Cl. 156/272.2; 428/421; 428/327; 428/66.4; 264/173.16; 264/255; 264/485; 264/478; 264/464; 264/471; 156/327

(57) ABSTRACT

A multilayer polymeric composite having a fluoropolymeric layer of a multiphase composition of a continuous phase of thermoplastic polymer material with a dispersed fluoroelastomeric amorphous phase provides a basis for improved gaskets, o-rings, seals, and flexible component members in assemblies. In one form, the multilayer polymeric composite is treated with radiation. The fluoropolymeric layer is remarkably thin while demonstrating excellent permeability resistance to fuels and amine bases.

### INTRODUCTION

This invention relates to multilayer polymeric composites and to articles formed of multilayer polymeric composites. In particular, the present invention relates to multilayer polymeric composites having a fluoropolymeric layer of a continuous thermoplastic phase and a dispersed amorphous phase comprising fluoroelastomer.

Fluoroelastomer rubber is a well-known material providing excellent resistance to heat, fuels, and chemicals. Fluoroelastomer thermoplastic vulcanizates have been developed to provide some of the features of fluoroelastomer rubber in a material that can be readily injection molded.

Multilayer polymeric, composites enable many of the benefits of modern life. Each layer of the composite contributes to the overall performance of the composite as viewed from the intended application.

What is needed is a way for fluoroelastomer performance to be smoothly incorporated into multilayer polymeric composites. This and other needs are achieved with the invention.

### SUMMARY

The invention provides a multilayer polymeric composite (“composite”) made of at least one polymeric structural layer and a fluoropolymeric layer cohered to at least one of the polymeric structural layer(s). The fluoropolymeric layer comprises a multiphase composition having a continuous phase of thermoplastic polymer material and a dispersed amorphous phase of fluoroelastomer.

The thermoplastic polymer material is optionally radiation crosslinked. The fluoroelastomer is either uncured or cured. In one embodiment, the fluoroelastomer is cured by a curing system combining a peroxide curing agent and a phenolic curing agent.

In various embodiments, the amorphous phase comprises cured or uncured fluoroelastomeric portions having independent diameters of from about 0.1 microns to about 100 microns, and the fluoroelastomer is from about 30 to about 85 weight percent of the fluoropolymeric layer. In yet other embodiments, the multiphase composition is derived from mixing uncured fluoroelastomer into the thermoplastic to provide from about 30 to about 95 weight percent of fluoroelastomer in the multiphase composition, and the multiphase composition is a co-continuous polymer matrix multiphase composition where the amorphous phase has a maximum cross-sectional diameter (thickness dimension) of from about 0.1 microns to about 100 microns.

Preferred thermoplastics include fluorine-containing fluoroplastics. Non-limiting examples include a polymer of vinylidene fluoride (PVDF), a copolymer of vinylidene fluoride-hexafluoropropylene (PVDF-HFP copolymer), a copolymer of vinylidene fluoride-chlorotrifluoroethylene (PVDF-CETFE copolymer), a copolymer of ethylene-tetrafluoroethylene (ETFE), a copolymer of ethylene-chlorotrifluoroethylene (ECTFE), and a terpolymer of tetrafluoroethylene-hexafluoropropylene-vinylidenefluoride (THV); and the fluoroelastomer is selected from the group consisting of a copolymer elastomer of hexafluoropropylene (HFP)-vinylidene fluoride (VdF), a terpolymer elastomer of tetrafluoroethylene (TFE)-hexafluoropropylene (HFP)-vinylidene fluoride (VdF), a copolymer elastomer of tetrafluoroethylene (TFE)-C₂-₄ olefin, and a terpolymer elastomer of tetrafluoroethylene (TFE)-C₂₋₄ olefin-vinylidene fluoride (VdF).

In preferred embodiments, the multilayer polymeric composite has a permeation constant of not greater than 25 gms-mm/m²/day to ASTM D-814 Fuel C gasoline. Preferably, the multilayer polymeric composite has a compression set value of not greater than 60. In yet another aspect, the fluoropolymeric layer is cohered to the polymeric structural layer with an adhesive layer.

The multilayer polymeric composite is configured, in one embodiment, to be a fuel hose with the polymeric structural layer being an outer layer of the fuel hose, the fluoropolymeric layer further comprising a dispersed phase of conductive particulate such that the fluoropolymeric layer has an electrical resistivity of less than about 1×10⁻³ Ohm-m at 20 degrees Celsius. The fluoropolymeric layer is cohered to the outer layer to provide an electrically conductive inner lining of the fuel hose. In still another embodiment, the multilayer polymeric composite is configured to be a tubular conduit, and the polymeric structural layer is an outer layer of the tubular conduit. In another embodiment, the fluoropolymeric layer comprises heat conductive filler.

In an illustrative embodiment, the fluoropolymeric layer encapsulates the polymeric structural layer such that the polymeric structural layer is a core in the multilayer polymeric composite. In a non-limiting example, the fluoropolymeric layer has a layer thickness of from about 0.5 of a mil to about 10 mils. Preferably, the ratio of the fluoropolymeric layer thickness to the composite thickness is from about 1:25 to about 1:250.

In another embodiment, the fluoropolymeric layer is an internal layer in the multilayer polymeric composite, cohering independently to two separate outside layers (optionally with the benefit of an adhesive layer). In exemplary embodiments, the fluoropolymeric layer is an elastomeric core encapsulated within the polymeric structural layer. In various embodiments, the fluoropolymeric layer is a relatively thin component of the composite.

The multilayer polymeric composite is configured, in alternative embodiments, to be any of a gasket, a dynamic seal, a static seal, and an o-ring. In examples of other embodiments, the multilayer polymeric composite is configured to be any of a pump diaphragm and a peristaltic pump flexure tube.

The invention is also for method for forming a multilayer polymeric composite according to the above, through cohering a fluoropolymeric layer according to the above-described composition to a polymeric structural layer to form the composite and, optionally, then irradiating the composite. The cohering can be through a standard forming process such as any of pultrusion, compression molding, multi-layer extrusion, co-extrusion, injection molding, transfer molding, and insert molding.

To illustrate one embodiment, a mandrel is made, the fluoropolymeric layer and the polymeric structural layer are pultruded onto the mandrel, and the mandrel is removed to leave the multilayer polymeric composite as a residual item.

Further areas of applicability will become apparent from the detailed description provided hereinafter. It should be understood that the detailed description and specific examples, while indicating embodiments of the invention, are intended for purposes of illustration only and are not intended to limit the scope of the invention.

### BRIEF DESCRIPTION OF THE DRAWINGS

The present invention will become more fully understood from the detailed description and the accompanying drawings of FIGS. 1 to 11.

FIG. 1 shows a ternary composition diagram for fluoropolymers derived from tetrafluoroethylene (TFE), hexfluoropropylene (HFP), and vinylidene fluoride;

FIG. 2A provides a cross-section view of a basic multilayer polymeric composite;

FIG. 2B provides a cross-section view of a basic multilayer polymeric composite where the layers are cohered with the benefit of an adhesive layer;

FIG. 3A provides a cross-section view of a multilayer polymeric composite having a plurality of polymeric structural layers;

FIG. 3B shows a cross-section view of a multilayer polymeric composite with a fluoropolymeric inner layer in independent cohesion to outside layers of the multilayer polymeric composite;

FIG. 4A shows a cross-section view of a multilayer polymeric composite with an encapsulated core;

FIG. 4B shows a perspective view of the multilayer polymeric composite of FIG. 4A;

FIGS. 5A, 5B, and 5C present circular cross-section end views in perspective reference views of three alternative embodiments of multilayer polymeric composite tubes or hoses incorporating a fluoropolymeric layer;

FIG. 6 shows a cross-section view of a general sealed assembly model;

FIG. 7 presents a cross-section view of an assembly profile of a compressible seal between two moveable rigid surfaces;

FIG. 8 presents a cross-section view of an assembly profile of a compressible seal statically deployed between two non-moveable rigid surfaces;

FIG. 9 presents a cross-section view of an assembly profile of a dynamic seal protecting a rotating component;

FIGS. 10A to 10F depict a number of circular cross-section end views in perspective reference views of alternative multilayer polymeric composite o-ring seal configurations with each configuration having a fluoropolymeric layer; and

FIG. 11 presents a cross-section view of seal detail for a clip-in dynamic seal.

It should be noted that the figures set forth herein are intended to exemplify the general characteristics of an apparatus, materials, and methods among those of this invention, for the purpose of the description of such embodiments herein. The figures may not precisely reflect the characteristics of any given embodiment, and are not necessarily intended to define or limit specific embodiments within the scope of this invention.

### DESCRIPTION

The following definitions and non-limiting guidelines must be considered in reviewing the description of this invention set forth herein.

The headings (such as “Introduction” and “Summary”) and sub-headings used herein are intended only for general organization of topics within the disclosure of the invention, and are not intended to limit the disclosure of the invention or any aspect thereof. In particular, subject matter disclosed in the “Introduction” may include aspects of technology within the scope of the invention, and may not constitute a recitation of prior art. Subject matter disclosed in the “Summary” is not an exhaustive or complete disclosure of the entire scope of the invention or any embodiments thereof.

The citation of references herein does not constitute an admission that those references are prior art or have any relevance to the patentability of the invention disclosed herein. All references cited in the Description section of this specification are hereby incorporated by reference in their entirety.

The description and specific examples, while indicating embodiments of the invention, are intended for purposes of illustration only and are not intended to limit the scope of the invention. Moreover, recitation of multiple embodiments having stated features is not intended to exclude other embodiments having additional features, or other embodiments incorporating different combinations the stated of features.

As used herein, the words “preferred” and “preferably” refer to embodiments of the invention that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention.

As used herein, the word “include,” and its variants, is intended to be non-limiting, such that recitation of items in a list is not to the exclusion of other like items that may also be useful in the materials, compositions, devices, and methods of this invention.

Most items of manufacture represent an intersection of considerations in both mechanical design and in materials design. In this regard, improvements in materials frequently are intertwined with improvements in mechanical design. The embodiments describe compounds, compositions, assemblies, and manufactured items that enable improvements in polymer material synthesis to be fully exploited.

The examples and other embodiments described herein are exemplary and not intended to be limiting in describing the full scope of compositions and methods of this invention. Equivalent changes, modifications and variations of specific embodiments, materials, compositions and methods may be made within the scope of the present invention, with substantially similar results.

The present invention provides, in various embodiments, multilayer polymeric composites having a fluoropolymeric layer cohered to a polymeric structural layer where the fluoropolymeric layer is a multiphase composition of continuous thermoplastic polymer material with a dispersed fluoroelastomeric amorphous phase.

Carbon-chain-based polymeric materials (polymers) are usefully defined as falling into one of three traditionally separate generic primary categories: thermoset materials (one type of plastic), thermoplastic materials (a second type of plastic), and elastomeric (or rubber-like) materials (elastomeric materials are not generally referenced as being “plastic” insofar as elastomers do not provide the property of a solid “finished” state). One important measurable consideration with respect to these three categories is the concept of a melting point—a point where a solid phase and a liquid phase of a material co-exist. A second important measurable consideration with respect to these three categories is the concept of a glass transition temperature. In this regard, a thermoset material essentially cannot be melted or liquefied after having been “set” or “cured” or “cross-linked”. Precursor component(s) to the thermoset plastic material are usually shaped in molten (or essentially liquid) form, but, once the setting process has executed, a melting point essentially does not exist for the material. A thermoplastic plastic material, in contrast, hardens into solid form, retains a melting point (or, for a few thermoplastic materials as further discussed below, a glass transition temperature of greater than 0 degrees Celsius) essentially indefinitely, and re-melts (albeit in some cases with a certain amount of degradation in general polymeric quality) after having been formed. An elastomeric (or rubber-like) material does not have a melting point; rather, the elastomer has a glass transition temperature of not greater than 0 degrees Celsius where the polymeric material demonstrates an ability to liquefy and usefully flow, but without co-existence of a solid phase and a liquid phase at a melting point.

In further consideration of melting points and glass transition temperatures, most thermoplastic materials have a melting (solidification) point associated with the presence of crystals in the thermoplastic polymer, but some thermoplastics (such as, without limitation, atactic polystyrene) are considered to be substantially amorphous with a characteristic glass transition temperature rather than a melting point. In this regard and as detailed above, elastomers and amorphous thermoplastics are differentiated by the ranges of their glass transition temperatures, with the glass transition temperature for an essentially amorphous thermoplastic being greater than 0 degrees Celsius and the glass transition temperature for an elastomer being not greater than 0 degrees Celsius.

Elastomers are frequently derived from elastomer gums or partially cured elastomer gums through the process of vulcanization (curing, or cross-linking). Such elastomer gum or partially cured elastomer gum forms of elastomer are denoted herein as uncured elastomers. Depending upon the degree of vulcanization in an elastomer, the glass transition temperature may increase to a value that is too high for any practical attempt at liquefaction of the vulcanizate. Vulcanization implements inter-bonding between elastomer chains to provide an elastomeric material more robust against deformation than a material made from the uncured or partially cured elastomers. In this regard, a measure of performance denoted as a “compression set value” is useful in measuring the degree of vulcanization (“curing”, “cross-linking”) in the elastomeric material. For the initial uncured elastomer form of the elastomer, when the elastomer material is in either a non-vulcanized state or in a state of vulcanization that is clearly preliminary to the final desired vulcanized state, a non-vulcanized compression set value is measured according to ASTM D395 Method B and establishes thereby an initial compressive set value for the particular elastomer that will be vulcanized (cured) to a desired compressive set value. Under extended vulcanization, the elastomer vulcanizes to a point where its compression set value achieves an essentially constant maximum respective to further vulcanization, and, in so doing, thereby defines a material where a fully vulcanized compression set value for the particular elastomer is measurable. In applications, the elastomer is vulcanized to a compression set value useful for the application.

Augmenting the above-mentioned three general primary categories of thermoset plastic materials, thermoplastic plastic materials, and elastomeric materials are two blended combinations of thermoplastic and elastomeric materials generally known as TPEs and TPVs. Thermoplastic elastomer (TPE) and thermoplastic vulcanizate (TPV) materials have been developed to partially combine the desired properties of thermoplastics with the desired properties of elastomers. As such, TPV materials are usually multi-phase mixtures of vulcanized elastomer in thermoplastic. Traditionally, the vulcanized elastomer (vulcanizate) phase and thermoplastic plastic phase co-exist in phase mixture after solidification of the thermoplastic phase; and the mixture is liquefied by heating the mixture above the melting point of the thermoplastic phase of the TPV. TPE materials are multi-phase mixtures, at the molecular level, of elastomer and thermoplastic and are derived by polymerizing together monomers and/or oligomers of elastomer and thermoplastic. TPVs and TPEs both have melting points enabled by their respective thermoplastic phase and/or molecular aspects.

The elastomeric phase in traditional TPV materials provides a compressive set value (as further discussed in the following paragraph) from about 50 to about 100 percent between a non-vulcanized compressive set value measured for elastomer gum in the initial combination of elastomeric gum (uncured elastomer) and thermoplastic used to make a thermoplastic vulcanizate and a fully vulcanized compressive set value measured for the vulcanizate in the thermoplastic vulcanizate after it has been extensively vulcanized.

With respect to a difference between a non-vulcanized compressive set value for an elastomer (in the uncured elastomer or elastomer gum state) and a fully-vulcanized compressive set value for an elastomer, it is to be noted that percentage in the 0 to about 100 percent range (between a non-vulcanized compression set value respective to the uncured elastomer or elastomer gum and to a fully-vulcanized compression set value respective to the elastomer) applies to the degree of vulcanization in the elastomer or elastomer gum rather than to percentage recovery in a determination of a particular compression set value. As an example, an elastomer gum prior to vulcanization (uncured elastomer for the example) has a non-vulcanized compression set value of 72. After extended vulcanization, the vulcanized elastomer demonstrates a fully vulcanized compression set value of 10. (It should be noted that even with a set value of 10, an object made with the fully vulcanized material may be capable of significant expansion from a compressed state, so as to expand 1000%, for example, from a thickness measurement under compression to a thickness measurement after compression is released). A difference between the compression set values of 72 and 10 indicate a range of 62 between the non-vulcanized compression set value respective to the uncured elastomer and a fully vulcanized compression set value respective to the cured elastomer. Since the compression set value decreased with vulcanization in this example, a compressive set value within the range of 50 to about 100 percent of a difference between a non-vulcanized compression set value respective to the uncured elastomer and a fully-vulcanized compression set value respective to the cured elastomer would therefore be achieved with a compressive set value between about 41 (50% between 72 and 10) and about 10 (the fully-vulcanized compression set value).

In various embodiments, uncured elastomers are characterized by a low level of vulcanization or cure as reflected or manifested in relatively low attainment of elastomeric properties. One of these properties is the compression set property. The compression set property of an uncured elastomer is less than 5 to 10 percent developed respective to the compression set value achieved during curing from the initially uncured to the fully-cured value as the elastomer is cured to achieve desired elastomeric properties for an application.

In one characterization of uncured elastomer, elastomer gum is effectively a relatively low molecular weight post-oligomer elastomeric precursor of a cured elastomeric material. More specifically, elastomer gum has a glass transition temperature, a decomposition temperature, and, at a temperature having a value that is not less than the glass transition temperature and not greater than the decomposition temperature, a compressive set value (as further described herein) from about 0 to about 5 percent of a difference between a non-vulcanized (non-cured) compressive set value for elastomer derived from the elastomer precursor gum and a fully-vulcanized (fully-cured) compressive set value for the derived elastomer. More specifically for fluoroelastomers, an elastomer gum has a Mooney viscosity of from about 0 to about 150 ML₁₊₁₀ at 121 degrees Celsius when the relative fully vulcanized (fully-cured) elastomer is fluoroelastomeric.

A multilayer polymeric composite according to the invention (for convenience, hereinafter referred to as “composite”) is formed in the embodiments from at least one polymeric structural layer and a fluoropolymeric layer cohered to the polymeric structural layer (or to at least one of the polymeric structural layers). The fluoropolymeric layer is a multiphase composition having a continuous phase of a thermoplastic polymer material and an amorphous phase comprising a fluoroelastomer where the amorphous phase is dispersed in the continuous phase. The thermoplastic phase has at least one of either (a) a glass transition temperature of 0 degrees Celsius or above or (b) a melting point.

In various embodiments, it is observed that a multiphase composition having a continuous phase of a thermoplastic polymer material and a dispersed amorphous phase of fluoroelastomer can be extruded and/or molded to provide a very thin fluoroelastomeric layer having structural integrity and chemo-resistive properties traditionally associated with articles made entirely of the fluoroelastomer. In this regard, a very thin (0.5 mil) fluoropolymeric layer having chemical resistance and high temperature properties comparable to chemical resistance and high temperature properties of thicker traditional FKM elastomer layers is one advantageous property and/or improvement that is beneficially observed in a composite when the fluoropolymeric layer comprises a multiphase composition having a continuous phase of a thermoplastic polymer material and an amorphous phase (comprising a fluoroelastomer) dispersed in the continuous phase in independent portions having independent diameters of from about 0.1 microns to about 100 microns.

In appreciating the ability to make very thin layers of fluoropolymer having chemical resistance and high temperature properties comparable to that of a traditional fluoroelastomer, traditional FKM elastomer (rubber) has been used for many years for items such as o-rings or gaskets. Such FKM rubber items have traditionally been compression molded to achieve minimum dimensions of not less than about 50 mils (about 3/64 of an inch). Items made of FKM rubber frequently undergo some additional dimensional adjustment during post-mold curing. While FKM-TPV (fluoroelastomer thermoplastic vulcanizate) materials were developed to, in part, provide a substantial degree of “FKM rubber functionality” in a material that could be readily injection molded and/or extruded, the injection molding and/or extrusion of layers of fluoroelastomer and thermoplastic blends at 0.01 of the thickness of traditional FKM rubber in some embodiments provides very beneficial precision in molding and/or extrusion; such functionality enables improvements in composites as will be further described herein.

In one embodiment, the fluoropolymeric layer provides a chemo-resistant layer in the composite characterized by an advantageous property and/or improvement that is beneficially observed in permeability resistance properties to gasoline fuels and also to attack by Bronsted-Lowry (amine) bases. Where the fluoroelastomer is peroxide cured, the benefit is further shown in the Examples as providing a gasoline permeation constant that is three times better (three times lower in value) than that of a fluorocarbon rubber that is also cured with peroxide. For uncured blends of thermoplastic and fluoroelastomer gum (where the fluoroelastomer is uncured), the benefit provides a measured gasoline permeation constant that is at least 10 times better (10 times lower in value) than that of a fluorocarbon rubber that is cured with peroxide.

The amorphous phase for the multiphase composition is provided in several different general fluoroelastomer compositional embodiments.

In one uncured fluoroelastomer embodiment, the fluoroelastomer is uncured (uncured fluoroelastomer as fluoroelastomer gum or as fluoroelastomer gum with a relatively minor degree of curing as described above) and is intermixed with the thermoplastic to provide either (a) a dispersion of independent amorphous phase portions having independent diameters of from about 0.1 microns to about 100 microns in the thermoplastic phase or (b) a co-continuous polymer matrix multiphase composition (an interpenetrated structure) having a maximum cross-sectional diameter of from about 0.1 micron to about 100 microns in the uncured fluoroelastomer. Further details in this regard are described in U.S. patent application Ser. No. 10/983,926 filed on Nov. 8, 2004, entitled ELASTOMER GUM POLYMER SYSTEMS, incorporated by reference herein.

In another embodiment, the amorphous phase of the fluoropolymeric layer contains cured fluoroelastomer dispersed in the thermoplastic continuous phase in independent amorphous phase portions having independent diameters of from about 0.1 microns to about 100 microns. In one embodiment, the independent amorphous phase portions comprise independent portions of cured elastomer derived from a process of dynamic vulcanization. In one embodiment, the dynamic vulcanization is effected with use of a single curing agent blended into the initial blend of thermoplastic and uncured fluoroelastomer. In an alternative embodiment, the dynamic vulcanization is effected with use of a curing agent blend for multi-curing the uncured fluoroelastomer into cured fluoroelastomer (as will be further described herein).

In another fluoropolymeric layer embodiment, the fluoroelastomeric amorphous phase is crosslinked by irradiation to provide radiation-cured fluoroelastomer in the fluoropolymeric layer. Illustratively, a precursor blend of uncured fluoroelastomer and thermoplastic is first mixed into either a dispersion of uncured fluoroelastomer and thermoplastic or a co-continuous composition (as described above), and the blend is then formed into a formed fluoropolymeric layer. The formed fluoropolymeric layer is then irradiated with sufficient radiation to crosslink the uncured fluoroelastomer and/or crosslink the thermoplastic into a material of radiation-cured fluoroelastomer and/or radiation-crosslinked thermoplastic. The radiation is provided from several alternative radiation sources: any of ultraviolet radiation, infrared radiation, ionizing radiation, electron beam radiation, x-ray radiation, an irradiating plasma, a discharging corona, and a combination of these.

As should be appreciated, if the thermoplastic is crosslinked, then the irradiated continuous thermoplastic phase will have a different melt behavior than the continuous thermoplastic phase prior to irradiation; accordingly, in a preferred embodiment, a composite is first formed with a fluoropolymeric layer derived from the un-irradiated material, and then the composite is irradiated to further provide the crosslinked fluoroelastomer in the amorphous phase of the multiphase composition of the fluoropolymeric layer of the composite. Further details in this regard are described in U.S. patent application Ser. No. 10/881,106 filed on Jun. 30, 2004, entitled ELECTRON BEAM INTER-CURING OF PLASTIC AND ELASTOMER BLENDS, incorporated by reference herein.

The above methods of mixing and/or dynamic vulcanization provide a dispersed amorphous phase in the thermoplastic phase. The dispersed fluoroelastomeric amorphous phase is thereby provided in amorphous portions having either diameters of from about 0.1 microns to about 100 microns or, in the case of a filamentary or filament-shaped amorphous portion, a cross-sectional maximum diameter from about 0.1 microns to about 100 microns. In various embodiments, dispersed fluoroelastomeric amorphous phase portions of these dimensions are believed to lead to an observed high effectiveness of permeation and chemical resistance in composites of the invention.

In another embodiment, the fluoroelastomer amorphous phase is crosslinked by dynamic vulcanization prior to exposure to radiation. Such irradiation tends to crosslink the thermoplastic without further affecting the crosslinked elastomer. The radiation is provided from several alternative radiation sources: any of ultraviolet radiation, infrared radiation, ionizing radiation, electron beam radiation, x-ray radiation, an irradiating plasma, a discharging corona, and a combination of these. As should be appreciated, if the thermoplastic is crosslinked, then the irradiated continuous thermoplastic phase will have a different melt behavior than the continuous thermoplastic phase prior to irradiation. Accordingly, in a preferred embodiment, a composite is first formed with a fluoropolymeric layer derived from the un-irradiated dynamically vulcanized fluoroelastomer vulcanizate, and then the composite is irradiated to further provide radiation-modified dynamically vulcanized thermoplastic fluoroelastomer as the fluoropolymeric layer.

Composites of the invention contain at least one polymeric structural layer to which a fluoropolymeric layer is cohered. The structural layer is of a dimension and a composition suitable for the application. In various embodiments, the structural layer is made of a thermoplastic, a thermoset, or an elastomeric (rubber) material. Non-limiting examples include: acrylic acid ester rubber/polyacrylate rubber thermoplastic vulcanizate, acrylonitrile-butadiene-styrene, amorphous nylon, cellulosic plastic, ethylene chlorotrifluoroethylene copolymer, epoxy resin, ethylene tetrafluoroethylene copolymer, ethylene acrylic rubber, ethylene acrylic rubber thermoplastic vulcanizate, ethylene-propylene-diamine monomer rubber/polypropylene thermoplastic vulcanizate, tetrafluoroethylene/hexafluoropropylene copolymer, fluoroelastomer, fluoroplastic, hydrogenated nitrile rubber, melamine-formaldehyde resin, tetrafluoroethylene/perfluoromethylvinyl ether copolymer, natural rubber, nitrile butyl rubber, nylon, nylon 6, nylon 610, nylon 612, nylon 63, nylon 64, nylon 66, perfluoroalkoxy/tetrafluoroethylene/perfluoromethylvinylether terpolymer, phenolic resin, polyacetal, polyacrylate, polyamide, polyamide thermoplastic, thermoplastic elastomer, polyamide-imide, polybutene, polybutylene, polycarbonate, polyester, polyester thermoset plastic, polyesteretherketone, polyethylene, polyethylene terephthalate, polyimide, polymethylmethacrylate, polyolefin, polyphenylene sulfide, polypropylene, polystyrene, polysulfone, polytetrafluoroethylene, polyurethane, polyurethane elastomer, polyvinyl chloride, polyvinylidene fluoride, ethylene-propylene-diene rubber/polypropylene thermoplastic vulcanizate, silicone, silicone-thermoplastic vulcanizate, thermoplastic polyurethane, polyurethane elastomer, thermoplastic silicone vulcanizate, tetrafluoroethylene/hexafluoropropylene/vinylidenefluoride terpolymer, polyamide/polyether thermoplastic block co-polymer elastomer (commercially available, for example, from Atofina under the Pebax® trade name), polyester/polyether thermoplastic block co-polymer elastomer (commercially available, for example, from DuPont under the Hytrel® trade name), and combinations thereof. Polymers made of combinations of these are used in a polymeric structural layer in yet other embodiments.

Thermoplastic polymer material in the multiphase composition of the fluoropolymeric layer is selected from material with suitable flow characteristics, physical properties, chemical properties, and compatibility with the environment of use. Non-limiting examples include: polyamide, nylon 6, nylon 66, nylon 64, nylon 63, nylon 610, nylon 612, amorphous nylon, polyester, polyethylene terephthalate, polystyrene, polymethyl methacrylate, thermoplastic polyurethane, polybutylene, polyesteretherketone, polyimide, fluoroplastic, polyvinylidene fluoride, polysulfone, polycarbonate, polyphenylene sulfide, polyethylene, polypropylene, polyacetal polymer, polyacetal, perfluoroalkoxy/tetrafluoroethylene/perfluoromethylvinylether terpolymer, tetrafluoroethylene/perfluoromethylvinylether copolymer, ethylene/tetrafluoroethylene copolymer, ethylene/chlorotrifluoroethylene copolymer, tetrafluoroethylene/hexafluoropropylene/vinylidenefluoride terpolymer, tetrafluoroethylene/hexafluoropropylene copolymer, polyester thermoplastic ester, polyester ether copolymer, polyamide ether copolymer, polyamide thermoplastic ester, polyamide/polyether thermoplastic block co-polymer elastomer (commercially available, as previously noted, from Atofina under the Pebax® trade name), polyester/polyether thermoplastic block co-polymer elastomer (commercially available, as previously noted, from DuPont under the Hytrel® trade name), and combinations thereof. Preferred thermoplastics for the multiphase compositions include thermoplastic elastomers with high temperature resistance. Examples of these include aforementioned Pebax® and Hytrel®.

Fluoroelastomer in the amorphous phase of the multiphase composition of the fluoropolymeric layer is selected from material with suitable flow characteristics, physical properties, chemical properties, and compatibility with the environment of use.

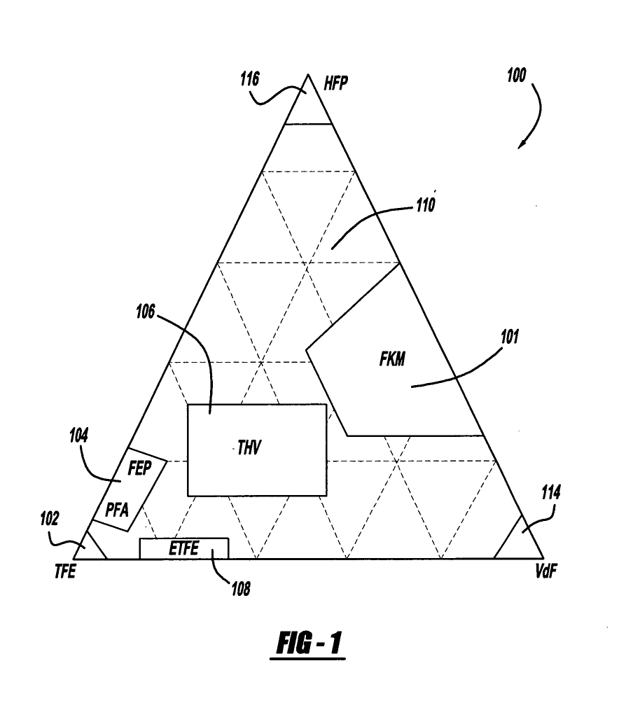

Further detail in the nature of the fluoroelastomer of the amorphous phase is appreciated from a consideration of FIG. 1, ternary composition diagram 100 showing tetrafluoroethylene (TFE), hexfluoropropylene (HFP), and vinylidene fluoride (VdF) weight percentage combinations for making various co-polymer elastomers. Region 101 defines blends of respective tetrafluoroethyl, hexfluoropropyl, and vinylidyl fluoride overall amounts that combine to form fluoroelastomer polymers of the type designated as FKM (for copolymer rubbers based on vinylidene fluoride). Region 104 defines blends of respective tetrafluoroethyl, hexfluoropropyl, and vinylidyl fluoride overall amounts that combine to form perfluoroalkoxy tetrafluoroethylene/perfluoromethylvinyl ether and tetrafluoroethylene/hexafluoropropylene polymers. Region 106 defines blends of respective tetrafluoroethyl, hexfluoropropyl, and vinylidyl fluoride overall amounts that combine to form tetrafluoroethylene/hexafluoropropylene/vinylidene fluoride polymers. Region 108 defines blends of respective tetrafluoroethyl, hexfluoropropyl, and vinylidyl fluoride overall amounts that combine to form ethylene tetrafluoroethylene polymers. Region 110 defines blends of respective tetrafluoroethyl, hexfluoropropyl, and vinylidyl fluoride overall amounts that traditionally have not generated useful co-polymers. Region 102 defines blends of respective tetrafluoroethyl, hexfluoropropyl, and vinylidyl fluoride overall amounts that combine to form polytetrafluoroethylene (PTFE) polymers. Region 114 defines blends of respective tetrafluoroethyl, hexfluoropropyl, and vinylidyl fluoride overall amounts that combine to form polyvinylidene fluoride (PVdF) polymers. Region 116 defines blends of respective tetrafluoroethyl, hexfluoropropyl, and vinylidyl fluoride overall amounts that combine to form polyhexfluoropropylene (PHFP) polymers.

Non-limiting examples of specific fluorocarbon elastomers for the amorphous phase of the fluoropolymer layer include:

(i) vinylidene fluoride/hexafluoropropylene copolymer fluoroelastomer having from about 66 weight percent to about 69 weight percent fluorine and a Mooney viscosity of from about 0 to about 130 ML₁₊₁₀ at 121 degrees Celsius (commercially available, for example, from DuPont under the Viton® trade name in the Viton® A series or from 3M under the Dyneon® trade name in the Dyneon® FE series);

(ii) vinylidene fluoride/perfluorovinyl ether/tetrafluoroethylene terpolymer fluoroelastomer having at least one cure site monomer and from about 64 weight percent to about 67 weight percent fluorine and a Mooney viscosity of from about 50 to about 100 ML₁₊₁₀ at 121 degrees Celsius (commercially available, for example, from DuPont under the Viton® GLT series or the Viton® GFLT series);

(iii) tetrafluoroethylene/propylene/vinylidene fluoride terpolymer fluoroelastomer having from about 59 weight percent to about 63 weight percent fluorine and a Mooney viscosity of from about 25 to about 45 ML₁₊₁₀ at 121 degrees Celsius (commercially available, for example, from Ashai under the Aflas® trade name in the Aflas® 200 series or from 3M in the Dyneon® BRE series);

(iv) tetrafluoroethylene/ethylene/perfluorovinyl ether terpolymer fluoroelastomer having at least one cure site monomer and from about 60 weight percent to about 65 weight percent fluorine and a Mooney viscosity of from about 40 to about 80 ML1₊₁₀ at 121 degrees Celsius (commercially available, for example, from DuPont under the Viton® ETP 900 series or the Viton® ETP 600 series);

(v) vinylidene fluoride/hexafluoropropylene/tetrafluoroethylene terpolymer fluoroelastomer having at least one cure site monomer and from about 66 weight percent to about 72.5 weight percent fluorine and a Mooney viscosity of from about 15 to about 90 ML₁₊₁₀ at 121 degrees Celsius (commercially available, for example, from Solvay under the Technoflon® trade name in the Technoflon® series or from from DuPont under the Viton® B series);

(vi) tetrafluoroethylene/propylene copolymer fluoroelastomer having about 57 weight percent fluorine and a Mooney viscosity of from about 25 to about 115 ML₁₊₁₀ at 121 degrees Celsius (commercially available, for example, from Asahi under the in the Aflas® 100 series or from DuPont under the Viton® TBR series);

(vii) tetrafluoroethylene/hexafluoropropylene/perfluorovinyl ether/vinylidene fluoride tetrapolymer fluoroelastomer having at least one cure site monomer and from about 59 weight percent to about 64 weight percent fluorine and a Mooney viscosity of from about 30 to about 70 ML1₊₁₀ at 121 degrees Celsius (commercially available, for example, from 3M under the in the Dyneon® LTFE series);

(viii) tetrafluoroethylene/perfluorovinyl ether copolymer fluoroelastomer having at least one cure site monomer and from about 69 weight percent to about 71 weight percent fluorine and a Mooney viscosity of from about 60 to about 120 ML1₊₁₀ at 121 degrees Celsius(commercially available, for example, from DuPont in the Viton® Kalrez series); and

(ix) fluoroelastomer corresponding to the formula
[-TFE_{q}-HFPᵣ-VdFₛ-]_{d}
where TFE is essentially tetrafluoroethyl, HFP is essentially hexfluoropropyl, VdF is essentially vinylidyl fluoride, and products qd and rd and sd collectively provide proportions of TFE, HFP, and VdF whose values are within element 101 of FIG. 1.

In a preferred embodiment, the thermoplastic polymer material of the multiphase composition of the fluoropolymeric layer is selected from the group consisting of a polymer of vinylidene fluoride (PVDF), a copolymer of vinylidene fluoride-hexafluoropropylene (PVDF-HFP copolymer), a copolymer of vinylidene fluoride-chlorotrifluoroethylene (PVDF-CETFE copolymer), a copolymer of ethylene-tetrafluoroethylene (ETFE), a copolymer of ethylene-chlorotrifluoroethylene (ECTFE), and a terpolymer of tetrafluoroethylene-hexafluoropropylene-vinylidenefluoride (THV); and the fluoroelastomer is selected from the group consisting of a copolymer elastomer of hexafluoropropylene (HFP)-vinylidene fluoride (VdF), a terpolymer elastomer of tetrafluoroethylene (TFE)-hexafluoropropylene (HFP)-vinylidene fluoride (VdF), a copolymer elastomer of tetrafluoroethylene (TFE)-C₂₋₄ olefin, and a terpolymer elastomer of tetrafluoroethylene (TFE)-C₂₋₄ olefin-vinylidene fluoride (VdF). Most preferably the continuous thermoplastic phase comprises fluoroplastic selected from the group consisting of polyvinylidene fluoride having a melt flow index from about 5 to about 40, and ethylene-tetrafluoroethylene copolymer having a having a melt flow index from about 5 to about 40.

In one embodiment, the multiphase composition of the fluoropolymeric layer in the invention is made by dynamic vulcanization where the curable fluoroelastomer vulcanizate is cured, or vulcanized, in the presence of the thermoplastic under conditions of high shear at a temperature above the melting point of the thermoplastic component. In an exemplary process, an appropriate curative or curative system is added to a blend of thermoplastic material and fluoroelastomeric material (such as uncured fluoroelastomer), and the mixture is heated at a temperature and for a time sufficient to effect vulcanization of the uncured fluoroelastomeric material in the presence of the thermoplastic material. Mechanical energy is applied to the mixture of fluoroelastomeric material, curative agent and thermoplastic material during the heating step. Thus dynamic vulcanization provides for mixing the fluoroelastomer and thermoplastic components in the presence of a curative agent and heating during the mixing to effect cure (cross-linking; vulcanization) of the fluoroelastomeric component. Alternatively, the uncured fluoroelastomeric material and thermoplastic material may be mixed for a time and at a shear rate sufficient to form a dispersion of the fluoroelastomeric material in a continuous thermoplastic phase. Thereafter, a curative agent may be added to the dispersion of uncured fluoroelastomeric material and thermoplastic material while continuing the mixing. Finally, the dispersion is heated while continuing to mix to produce the processable multiphase composition for the fluoropolymeric layer of the invention.

Fluoroelastomer is thus simultaneously crosslinked and dispersed as particles or portions within the thermoplastic matrix. In various embodiments, dynamic vulcanization is effected by mixing the fluoroelastomeric and thermoplastic components at elevated temperature in the presence of a curative in conventional mixing equipment such as roll mills, Moriyama mixers, Banbury mixers, Brabender mixers, continuous mixers, mixing extruders such as single and twin-screw extruders, and the like. An advantageous characteristic of dynamically cured compositions is that, notwithstanding the fact that the fluoroelastomeric component is fully cured, the compositions can be processed and reprocessed by conventional plastic processing techniques such as extrusion, injection molding and compression molding. Scrap or flashing can be salvaged and reprocessed.

Heating and mixing or mastication at vulcanization temperatures are generally adequate to complete the vulcanization reaction in a few minutes or less, but if shorter vulcanization times are desired, higher temperatures and/or higher shear may be used. A suitable range of vulcanization temperature is from about the melting temperature of the thermoplastic material (typically 120° C.) to about 300° C. or more. Typically, the range is from about 150° C. to about 250° C. A preferred range of vulcanization temperatures is from about 180° C. to about 220° C. It is preferred that mixing continues without interruption until vulcanization occurs or is complete.

If appreciable curing is allowed after mixing has stopped, an unprocessable thermoplastic vulcanizate may be obtained. In this case, a kind of post curing step may be carried out to complete the curing process. In some embodiments, the post curing takes the form of continuing to mix the fluoroelastomer and thermoplastic during a cool-down period.

Curing systems for fluorocarbon elastomers are well known. In a radical system, a free radical on the fluorocarbon elastomer is induced by reaction with a radical agent such as an organic peroxide compound. Then the fluorocarbon elastomer is cross-linked by the reaction of a crosslinking co-agent with the induced free radical. Alternatively, the fluorocarbon elastomer is dynamically vulcanized with a phenolic curing agent blended into the initial blend of thermoplastic and uncured fluoroelastomer, with a peroxide curing agent blended into the initial blend of thermoplastic and uncured fluoroelastomer, or with both a phenolic agent and a peroxide agent multi-curing process.

As previously noted, uncured fluoroelastomer copolymers prepared for dynamic vulcanization preferably contain relatively minor amounts of cure site monomers (CSM), discussed further below. The presence of cure site monomers in an elastomer tends to increase the rate at which the elastomer can be cured by peroxides. Preferred copolymer fluorocarbon elastomers include VDF/HFP, VDF/HFP/CSM, VDF/HFP/TFE, VDF/HFP/TFE/CSM, VDF/PFVE/TFE/CSM, TFE/Pr, TFE/Pr/VDF, TFE/Et/PFVE/VDF/CSM, TFE/Et/PFVE/CSM and TFE/PFVE/CSM. The elastomer designation gives the monomers from which the elastomer gums are synthesized. In various embodiments, the elastomer gums have viscosities that give a Mooney viscosity in the range generally of 15-160 (ML1+10, large rotor at 121° C.), which can be selected for a combination of flow and physical properties. Elastomer suppliers include Dyneon (3M), Asahi Glass Fluoropolymers, Solvay/Ausimont, Dupont, and Daikin.

The cure site monomers are preferably selected from the group consisting of brominated, chlorinated, and iodinated olefins; brominated, chlorinated, and iodinated unsaturated ethers; and non-conjugated dienes. Halogenated cure sites may be copolymerized cure site monomers or halogen atoms that are present at terminal positions of the fluoroelastomer polymer chain. The cure site monomers, reactive double bonds or halogenated end groups are capable of reacting to form crosslinks, especially under conditions of catalysis or initiation by the action of peroxides.

Other cure monomers may be used that introduce low levels, preferably less than or equal about 5 mole %, more preferably less than or equal about 3 mole %, of functional groups such as epoxy, carboxylic acid, carboxylic acid halide, carboxylic ester, carboxylate salts, sulfonic acid groups, sulfonic acid alkyl esters, and sulfonic acid salts. Such monomers and cure are described for example in Kamiya et al., U.S. Pat. No. 5,354,811.

Fluorocarbon elastomers based on cure site monomers are commercially available. Non-limiting examples include Viton GF, GLT-305, GLT-505, GBL-200, and GBL-900 grades from DuPont. Others include the G-900 and LT series from Daikin, the FX series and the RE series from NOK, and Tecnoflon P457 and P757 from Solvay.

A wide variety of fluorocarbon elastomers may be crosslinked or cured by a combination of a peroxide curative agent and a crosslinking co-agent. Generally, elastomers are subject to peroxide crosslinking if they contain bonds, either in the side chain or in the main chain, other than carbon fluorine bonds. For example, the peroxide curative agent may react with a carbon hydrogen bond to produce a free radical that can be further crosslinked by reaction with the crosslinking co-agent. In a preferred embodiment, peroxide curable elastomers are those that contain cure site monomers described above. The cure site monomers introduce functional groups—such as carbon bromine bonds, carbon iodine bonds, or double bonds—that serve as a site of attack by the peroxide curative agent. The kinetics of the peroxide cure are affected by the presence and nature of any cure site monomers present in the fluorocarbon elastomers. As a rule, the curing of an elastomer containing a cure site monomer is significantly faster than that of elastomers without cure site monomers.

Preferred peroxide curative agents are organic peroxides, for example, dialkyl peroxides. In general, an organic peroxide compound may be selected to function as a curing agent for the composition in the presence of the other ingredients and under the temperatures to be used in the curing operation without causing any harmful amount of curing during mixing or other operations which are to precede the curing operation. A dialkyl peroxide which decomposes at a temperature above 49° C. is especially preferred when the composition is to be subjected to processing at elevated temperatures before it is cured. In many cases one will prefer to use a di-tertiarybutyl peroxide having a tertiary carbon atom attached to a peroxy oxygen. Non-limiting examples include 2,5-dimethyl-2,5-di(tert-butylperoxy)-3-hexyne; 2,5-dimethyl-2,5-di(tert-butylperoxy) hexane; and 1,3-bis-(t-butylperoxyisopropyl)benzene. Other non-limiting examples of peroxide curative agent include dicumyl peroxide, dibenzoyl peroxide, tertiary butyl perbenzoate, di[1,3-dimethyl-3-(t-butylperoxy)butyl]carbonate, and the like.

One or more crosslinking co-agents may be combined with the peroxide. Examples include triallyl cyanurate; triallyl isocyanurate; tri(methallyl)-isocyanurate; tris(diallylamine)-s-triazine, triallyl phosphite; N,N-diallyl acrylamide; hexaallyl phosphoramide; N,N,N′,N′-tetraallyl terephthalamide; N,N,N′,N′-tetraallyl malonamide; trivinyl isocyanurate; 2,4,6-trivinyl methyltrisiloxane; and tri(5-norbornene-2-methylene) cyanurate.

Another group of fluorocarbon elastomers is curable by the action of various polyols. Curing with the polyol crosslinking agents is also referred to as phenol cure (phenolic cure) because phenols are commonly used polyols for the purpose. Many of the fluorocarbon elastomers that can be cured with polyols can also be cured with peroxides. The curability with either of the curing systems, and the relative rates of cure, depend on conditions during the dynamic vulcanization described below.

Phenol or polyol curative systems for fluorocarbon elastomers contain onium salts and one or more polyol crosslinking agents. In addition, crosslinking by phenol and polyol agents is accelerated by the presence in mixtures of phenol curing accelerators or curing stabilizers. Commonly used curing accelerators include acid acceptor compounds such as oxides and hydroxides of divalent metals. Non-limiting examples include calcium hydroxide, magnesium oxide, calcium oxide, and zinc oxide. In many embodiments, the rate of cure by phenol curing agents is significantly reduced when the acid acceptor compounds are not present in mixtures being dynamically vulcanized. In other words, even though a commercial embodiment may contain a phenol curable elastomer and a phenol and onium curing agent incorporated into the elastomer, the rate of phenol cure will nevertheless be very slow or nonexistent if the mixture contains no added acid acceptor compounds.

After dynamic vulcanization, a homogeneous mixture is obtained, wherein the cured fluoroelastomer is in the form of small dispersed portions (particles) having independent diameters of from about 0.1 microns to about 100 microns. In this regard, the portions preferably essentially have an average particle (or portion) size smaller than about 50 microns, preferably of an average particle size smaller than about 25 microns, more preferably of an average size smaller than about 10 microns or less, and still more preferably of an average particle size of 5 microns or less.

The progress of the vulcanization may be monitored through periodic measurement of the mixing torque or the mixing energy required by the mixing process. The mixing torque or mixing energy curve generally goes through a maximum after which mixing can be continued somewhat longer to improve the fabricability of the blend. If desired, one can add additional ingredients, such as the stabilizer package, after the dynamic vulcanization is complete. The stabilizer package is preferably added to the thermoplastic vulcanizate after vulcanization has been essentially completed, i.e., the curative has been essentially consumed.

The processable multiphase compositions of the invention may be manufactured in a batch process or a continuous process.

In a batch process, predetermined charges of fluoroelastomeric material, thermoplastic material and curative agents are added to a mixing apparatus. In a typical batch procedure, the fluoroelastomeric material and thermoplastic material are first mixed, blended, masticated or otherwise physically combined until a desired particle size of fluoroelastomeric material is provided in a continuous phase of thermoplastic material. When the structure of the fluoroelastomeric material is as desired, a curative agent may be added while continuing to apply mechanical energy to mix the fluoroelastomeric material and thermoplastic material. Curing is effected by heating or continuing to heat the mixing combination of thermoplastic and fluoroelastomeric material in the presence of the curative agent. When cure is complete, the processable multiphase composition may be removed from the reaction vessel (mixing chamber) for further processing.

It is preferred to mix the fluoroelastomeric material and thermoplastic material at a temperature where the thermoplastic material softens and flows. If such a temperature is below that at which the curative agent is activated, the curative agent may be a part of the mixture during the initial particle dispersion step of the batch process. In some embodiments, a curative is combined with the fluoroelastomeric and thermoplastic polymeric material at a temperature below the curing temperature. When the desired dispersion is achieved, the temperature may be increased to effect cure. In one embodiment, commercially available fluoroelastomeric materials are used that contain a curative pre-formulated into the fluoroelastomer. However, if the curative agent is activated at the temperature of initial mixing, it is preferred to leave out the curative until the desired particle size distribution of the fluoroelastomeric material in the thermoplastic matrix is achieved. In another embodiment, curative is added after the fluoroelastomeric and thermoplastic materials are mixed. Thereafter, in a preferred embodiment, the curative agent is added to a mixture of fluoroelastomeric particles in thermoplastic material while the entire mixture continues to be mechanically stirred, agitated or otherwise mixed.

Continuous processes may also be used to prepare the processable multiphase composition compositions of the invention. In a preferred embodiment, a twin screw extruder apparatus, either co-rotation or counter-rotation screw type is provided with ports for material addition and reaction chambers made up of modular components of the twin screw apparatus. In a typical continuous procedure, thermoplastic material and fluoroelastomeric material are combined together by inserting them into the screw extruder together in a first hopper using a feeder (loss-in-weight or volumetric feeder). Temperature and screw parameters may be adjusted to provide a proper temperature and shear to effect the desired mixing and particle size distribution of an uncured fluoroelastomeric component in a thermoplastic polymer material matrix. Mixing duration may be controlled either by adjusting the length of the extrusion apparatus and/or by controlling the speed of screw rotation for the mixture of fluoroelastomeric material and thermoplastic material during the mixing phase. The degree of mixing may also be controlled by the mixing screw element configuration in the screw shaft, such as intensive, medium or mild screw designs. Then, at a downstream port, by using a side feeder (loss-in-weight or volumetric feeder), the curative agent may be added continuously to the mixture of thermoplastic material and fluoroelastomeric material as it continues to travel down the twin screw extrusion pathway. Downstream of the curative additive port, the mixing parameters and transit time may be varied as described above. By adjusting the shear rate, temperature, duration of mixing, mixing screw element configuration, as well as the time of adding the curative agent, processable multiphase composition compositions of the invention may be made in a continuous process. As in the batch process, the fluoroelastomeric material may be commercially formulated to contain a curative agent, generally a phenol or phenol resin curative.

The compositions and articles of the invention will contain a sufficient amount of vulcanized fluoroelastomeric material (“rubber”) to form a rubbery composition of matter; that is, they will exhibit a desirable combination of flexibility, softness, and compression set. Preferably, the compositions should comprise from about 30 to about 85 weight percent of the fluoroelastomeric amorphous phase, preferably at least about 35 parts by weight fluoroelastomer, even more preferably at least about 45 parts by weight fluoroelastomer, and still more preferably at least about 50 parts by weight fluoroelastomer vulcanizate per 100 parts by weight of the fluoroelastomer vulcanizate and thermoplastic polymer combined. More specifically, the amount of cured fluoroelastomer vulcanizate within the thermoplastic vulcanizate is generally from about 30 to about 95 percent by weight, preferably from about 35 to about 85 percent by weight, and more preferably from about 50 to about 80 percent by weight of the total weight of the fluoroelastomer vulcanizate and the thermoplastic polymer combined.

The amount of thermoplastic polymer within the processable multiphase composition compositions of the invention is generally from about 15 to about 70 percent by weight, preferably from about 15 to about 65 percent by weight and more preferably from about 20 to about 50 percent by weight of the total weight of the fluoroelastomer vulcanizate and the thermoplastic combined.

As noted above, one embodiment of a composite has a fluoropolymeric layer derived from a processable multiphase composition including a cured fluoroelastomer vulcanizate and a thermoplastic polymer. Preferably, the thermoplastic vulcanizate is a homogeneous mixture wherein the fluoroelastomer vulcanizate is in the form of finely divided and well-dispersed fluoroelastomer vulcanizate particles within a non-vulcanized matrix. It should be understood, however, that the thermoplastic vulcanizates of the this invention are not limited to those containing discrete phases inasmuch as the compositions of this invention may also include other morphologies such as co-continuous morphologies.

The term vulcanized or cured fluoroelastomer vulcanizate refers to a synthetic fluoroelastomer vulcanizate that has undergone at least a partial cure. The degree of cure can be measured in one method by determining the amount of fluoroelastomer vulcanizate that is extractable from the thermoplastic vulcanizate by using boiling xylene or cyclohexane as an extractant. This method is disclosed in U.S. Pat. No. 4,311,628. By using this method as a basis, the cured fluoroelastomer vulcanizate of this invention will have a degree of cure where not more than 15 percent of the fluoroelastomer vulcanizate is extractable, preferably not more than 10 percent of the fluoroelastomer vulcanizate is extractable, and more preferably not more than 5 percent of the fluoroelastomer vulcanizate is extractable. In an especially preferred embodiment, the fluoroelastomer is technologically fully vulcanized. The term fully vulcanized refers to a state of cure such that the fluoroelastomer crosslink density is at least 7×10⁻⁵ moles per ml or such that the fluoroelastomer is less than about three percent extractable by cyclohexane at 23° C.

The degree of cure can be determined by the cross-link density of the rubber. This, however, must be determined indirectly because the presence of the thermoplastic polymer interferes with the determination. Accordingly, the same fluoroelastomer vulcanizate as present in the blend is treated under conditions with respect to time, temperature, and amount of curative that result in a fully cured product as demonstrated by its cross-link density. This cross-link density is then assigned to the blend similarly treated. In general, a cross-link density of about 7×10⁻⁵ or more moles per milliliter of fluoroelastomer vulcanizate is representative of the values reported for fully cured fluoroelastomeric copolymers. Accordingly, it is preferred that the compositions of this invention are vulcanized to an extent that corresponds to vulcanizing the same fluoroelastomer vulcanizate as in the blend statically cured under pressure in a mold with such amounts of the same curative as in the blend and under such conditions of time and temperature to give a cross-link density greater than about 7×10⁻⁵ moles per milliliter of fluoroelastomer vulcanizate and preferably greater than about 1×10⁻⁴ moles per milliliter of rubber.

A previously described fluoroelastomer gum and thermoplastic mixture is used for the fluoropolymeric layer in some embodiments as formulated, without further curing. In alternative embodiments, a derived material in the fluoropolymer layer is achieved by curing a previously described fluoroelastomer gum and thermoplastic mixture to modify the fluoroelastomer gum phase into vulcanized fluoroelastomer and provide thereby the amorphous phase of the multiphase composition in the fluoropolymeric layer. In some embodiments, the curing is achieved by mixing a curing agent into the fluoroelastomer gum and thermoplastic mixture just prior to molding the fluoroelastomer gum mixture into the fluoropolymeric layer of a desired article. In this regard, a curing agent of any of a bisphenol, peroxide, or a combination thereof is mixed into the uncured fluoroelastomer (fluoroelastomer gum).

In a multi-curing process, the uncured fluoroelastomer is prepared with appropriate cure site monomers for both phenol curing and peroxide curing. In one embodiment, phenolic curing agent is added to the initial blend of thermoplastic and uncured fluoroelastomer and the blend is dynamically vulcanized until a first stage of curing has been achieved. Peroxide curing agent is then added to the initial blend of thermoplastic and uncured fluoroelastomer and the blend is further dynamically vulcanized until full curing has been achieved. When a curing agent combination or curative system (such as, without limitation, a phenol and a peroxide curing agent) for multi-curing the uncured fluoroelastomer into vulcanized fluoroelastomer is used, the curing agent combination is introduced into the thermoplastic and uncured fluoroelastomer in one embodiment as a blend of the differentiated curing agents; in an alternative embodiment, the curing agent combination is introduced into the thermoplastic and uncured fluoroelastomer in a plurality of stages.

In embodiments with uncured fluoroelastomer, one method for making the multiphase composition of the fluoropolymeric layer is to mix the uncured (gum) fluoroelastomer component and the thermoplastic polymer with a conventional mixing system such as a batch polymer mixer, a roll mill, a continuous mixer, a single-screw mixing extruder, a twin-screw extruder mixing extruder, and the like until the uncured fluoroelastomer has been fully mixed and the uncured fluoroelastomeric amorphous phase portions (particles) have independent diameters (or independent maximum cross sectional diameters) of from about 0.1 microns to about 100 microns in the thermoplastic phase. In one embodiment, the multiphase composition is derived from mixing uncured fluoroelastomer into the thermoplastic to provide from about 30 to about 95 weight percent of fluoroelastomer in the multiphase composition, and the uncured fluoroelastomer is mixed to provide a co-continuous polymer matrix multiphase composition having independent uncured fluoroelastomer portion cross-sectional maximum diameters (phase cross-sectional thickness dimensions as measured at various locations in the co-continuous polymer matrix multiphase composition) of from about 0.1 microns to about 100 microns.

Mixing of different polymeric phases is controlled by relative viscosity between two initial polymeric fluids (where the first polymeric fluid has a first viscosity and the second polymeric fluid has a second viscosity). The phases are differentiated during admixing of the admixture from the two initial polymeric fluids. In this regard, the phase having the lower viscosity of the two phases will generally encapsulate the phase having the higher viscosity. The lower viscosity phase will therefore usually become the continuous phase in the admixture, and the higher viscosity phase will become the dispersed phase. When the viscosities are essentially equal, the two phases will form a co-continuous phase matrix or polymer system (also denoted as an interpenetrated structure) of polymer chains and/or minutely dimensioned polymeric portions. Accordingly, in general dependence upon the relative viscosities of the mixed fluoroelastomer and thermoplastic, several embodiments of mixed compositions derive from the general mixing approach. Preferably, each of the vulcanized, partially vulcanized, or gum elastomeric dispersed portions in a polymeric admixture has a cross-sectional diameter from about 0.1 microns to about 100 microns. For essentially spherical particles, this corresponds to the diameter of the spheres, while for filamentary particles it is the diameter of the cross sectional area of the filament. In another embodiment, the fluoroelastomeric and thermoplastic components are intermixed at elevated temperature in the presence of an additive package in conventional mixing equipment as noted above. Electrically conductive particulate and/or filler (including, for example, heat conductive filler), if used and as further discussed herein, are then mixed into the polymeric blend until fully dispersed to yield an electrically conductive material and/or filler-enhanced multiphase composition for the fluoropolymeric layer. In one embodiment, the uncured fluoroelastomer component and the thermoplastic polymer and the optional conductive (and optional filler) particulate are simultaneously mixed with a conventional mixing system such as a roll mill, continuous mixer, a single-screw mixing extruder, a twin-screw extruder mixing extruder, and the like until the filler and/or conductive material has been fully mixed.

In a preferred embodiment, plasticizers, extender oils, synthetic processing oils, or a combination thereof may be also used in any of the polymers used for composite layers in the invention. Respective to the multiphase composition of the fluoropolymeric layer, the type of processing oil selected will typically be consistent with that ordinarily used in conjunction with the specific fluoroelastomer vulcanizate present in the multiphase composition. The extender oils may include, but are not limited to, aromatic, naphthenic, and paraffinic extender oils. Preferred synthetic processing oils include polylinear-olefins. The extender oils may also include organic esters, alkyl ethers, or combinations thereof. As disclosed in U.S. Pat. No. 5,397,832, it has been found that the addition of certain low to medium molecular weight organic esters and alkyl ether esters to the compositions of the invention lowers the Tg in polyolefin and fluoroelastomer vulcanizate components, and improves the low temperatures properties of the overall fluoropolymeric layer, particularly flexibility and strength. These organic esters and alkyl ether esters generally have a molecular weight that is generally less than about 10,000. Particularly suitable esters include monomeric and oligomeric materials having an average molecular weight below about 2000, and preferably below about 600. In one embodiment, the esters may be either aliphatic mono- or diesters or alternatively oligomeric aliphatic esters or alkyl ether esters.

In addition to the fluoroelastomeric material, the thermoplastic polymeric material, and curative, the processable multiphase compositions for the fluoropolymeric layer in composites of this invention may include other additives such as stabilizers processing aids, curing accelerators, fillers, pigments, adhesives, tackifiers, and waxes. The properties of the compositions and articles of the invention may be modified, either before or after vulcanization, by the addition of ingredients that are conventional in the compounding of rubber, thermoplastics, and blends thereof.

A wide variety of processing aids may be used, including plasticizers and mold release agents. Non-limiting examples of processing aids include Caranuba wax, phthalate ester plasticizers such as dioctylphthalate (DOP) and dibutylphthalate silicate (DBS), fatty acid salts such zinc stearate and sodium stearate, polyethylene wax, and keramide. In some embodiments, high temperature processing aids are preferred. Such include, without limitation, linear fatty alcohols such as blends of C₁₀-C₂₈ alcohols, organosilicones, and functionalized perfluoropolyethers. In some embodiments, the compositions contain about 1 to about 15% by weight processing aids, preferably about 5 to about 10% by weight.

Acid acceptor compounds are commonly used as curing accelerators or curing stabilizers. Preferred acid acceptor compounds include oxides and hydroxides of divalent metals. Non-limiting examples include Ca (OH)₂, MgO, CaO, and ZnO.

In one embodiment, filler (particulate material contributing to the performance properties of the compounded elastomer gum mixture respective to such properties as, without limitation, bulk, weight, thermal conductivity, electrical conductivity, and/or viscosity while being essentially chemically inert or essentially reactively insignificant respective to chemical reactions within the compounded polymer) is also mixed into the formulation. The filler particulate is any material such as, without limitation, fiberglass, ceramic, or glass microspheres preferably having a mean particle size from about 5 to about 120 microns; carbon nanotubes; or other non-limiting examples of fillers including both organic and inorganic fillers such as, barium sulfate, zinc sulfide, carbon black, silica, titanium dioxide, clay, talc, fiber glass, fumed silica and discontinuous fibers such as mineral fibers, wood cellulose fibers, carbon fiber, boron fiber, and aramid fiber (Kevlar); and other ground materials such as ground rubber particulate, or polytetrafluoroethylene particulate having a mean particle size from about 5 to about 50 microns; Some non-limiting examples of processing additives include stearic acid and lauric acid. The addition of carbon black, extender oil, or both, preferably prior to dynamic vulcanization, is particularly preferred. Non-limiting examples of carbon black fillers include SAF black, HAF black, SRP black and Austin black. Carbon black improves the tensile strength, and an extender oil can improve processability, the resistance to oil swell, heat stability, hysteresis-related properties, cost, and permanent set. In a preferred embodiment, fillers such as carbon black may make up to about 40% by weight of the total weight of the compositions of the invention. Preferably, the compositions comprise 1-40 weight percent of filler. In other embodiments, the filler makes up 10 to 25 weight percent of the compositions.

Electrically conductive filler is used in the fluoropolymeric layer of some composite embodiments such as, for example and without limitation, a fuel hose composite having the fluoropolymeric layer as the inside layer of the fuel hose. In this regard, thermoset plastic materials, thermoplastic plastic materials, elastomeric materials, thermoplastic elastomer materials, and thermoplastic vulcanizate materials generally are not considered to be electrically conductive. As such, electrical charge buildup on a surface of an article (such as, in non-limiting example, a fuel line) made of these materials can occur to provide a “static charge” on the surface when a hydrocarbon fuel flows through the article. When discharge of the charge buildup occurs to an electrically conductive material proximate to such a charged surface, an electrical spark manifests the essentially instantaneous current flowing between the charged surface and the electrical conductor. Such a spark can be hazardous if the article is in service in applications or environments where flammable or explosive materials are present. Rapid discharge of static electricity can also damage some items (for example, without limitation, microelectronic articles) as critical electrical insulation is subjected to an instantaneous surge of electrical energy. Grounded articles made of materials having an electrical resistivity of less than about of 1×10⁻³ Ohm-m at 20 degrees Celsius are generally desired to avoid electrical charge buildup. Accordingly, in one embodiment of a material for a fuel hose embodiment, a dispersed phase of conductive particulate is provided in a fluoropolymer material to provide an electrically conductive fluoropolymeric material having an post-cured electrical resistivity of less than about of 1×10⁻³ Ohm-m at 20 degrees Celsius. This dispersed phase is made of a plurality of conductive particles dispersed in a continuous polymeric phase of fluoropolymer. In this regard, when, in some embodiments, the continuous polymeric phase of fluoropolymer is itself a multi-polymeric-phase polymer blend and/or mixture, the dispersed phase of conductive particles are preferably dispersed throughout the various polymeric phases without specificity to any one of the polymeric phases in the multi-polymeric-phase polymer. Further details in this regard are described in U.S. patent application Ser. No. 10/983,947 filed on Nov. 8, 2004. entitled FUEL HOSE WITH A FLUOROPOLYMER INNER LAYER, incorporated by reference herein.

The conductive particles used in alternative embodiments of electrically conductive polymeric materials for electrically conductive composites such as (without limitation) fuel hose embodiments include conductive carbon black, conductive carbon fiber, conductive carbon nanotubes, conductive graphite powder, conductive graphite fiber, bronze powder, bronze fiber, steel powder, steel fiber, iron powder, iron fiber, copper powder, copper fiber, silver powder, silver fiber, aluminum powder, aluminum fiber, nickel powder, nickel fiber, wolfram powder, wolfram fiber, gold powder, gold fiber, copper-manganese alloy powder, copper-manganese fiber, and combinations thereof.

In an alternative embodiment, a heat conductive particulate is dispersed in the fluoropolymeric layer in the same general manner as electrically conductive particulate but at a concentration appropriate to achieve a desired heat transfer rate for an intended application. The heat conductive particles used in alternative embodiments include bronze powder, bronze fiber, steel powder, steel fiber, iron powder, iron fiber, copper powder, copper fiber, silver powder, silver fiber, aluminum powder, aluminum fiber, nickel powder, nickel fiber, wolfram powder, wolfram fiber, gold powder, gold fiber, copper-manganese alloy powder, copper-manganese fiber, and combinations thereof.

In one embodiment, the fluoropolymeric layer is cohered to a structural polymer layer by irradiation treatment without benefit of an adhesive layer. In other embodiments, the fluoropolymeric layer is cohered to a structural polymer layer with an adhesive layer. The use of irradiation to inter-bond layers or to inter-bond an adhesive layer to the fluoropolymeric layer and to the structural polymer layer also has a benefit in the broad spectrum of materials that are candidates for the adhesive layer of the composite as further described in U.S. patent application Ser. No. 10/881,677 filed on Jun. 30, 2004, entitled ELECTRON BEAM CURING IN A COMPOSITE HAVING A FLOW RESISTANT ADHESIVE LAYER, incorporated by reference herein. In alternative embodiments, the adhesive layer is any of acrylic acid ester rubber/polyacrylate rubber thermoplastic vulcanizate, acrylonitrile-butadiene-styrene terpolymer, amorphous nylon, cellulosic plastic, ethylene/chlorotrifluoroethylene copolymer, epoxy resin, ethylene/tetrafluoroethylene copolymer, ethylene acrylic rubber, ethylene acrylic rubber thermoplastic vulcanizate, ethylene-propylene-diamine monomer rubber/polypropylene thermoplastic vulcanizate, tetrafluoroethylene/hexafluoropropylene copolymer, fluoroelastomer, fluoroelastomer thermoplastic vulcanizate, fluoroplastic, hydrogenated nitrile rubber, melamine-formaldehyde resin, tetrafluoroethylene/perfluoromethylvinylether copolymer, natural rubber, nitrile butyl rubber, nylon, nylon 6, nylon 610, nylon 612, nylon 63, nylon 64, nylon 66, perfluoroalkoxy/tetrafluoroethylene/perfluoromethylvinylether terpolymer, phenolic resin, polyacetal, polyacrylate, polyamide, polyamide thermoplastic, thermoplastic elastomer, polyamide-imide, polybutene, polybutylene, polycarbonate, polyester, polyester thermoplastic, thermoplastic elastomer, polyesteretherketone, polyethylene, polyethylene terephthalate, polyimide, polymethylmethacrylate, polyolefin, polyphenylene sulfide, polypropylene, polystyrene, polysulfone, polytetrafluoroethylene, polyurethane, polyurethane elastomer, polyvinyl chloride, polyvinylidene fluoride, ethylene propylene dimethyl/polypropylene thermoplastic vulcanizate, silicone, silicone-thermoplastic vulcanizate, thermoplastic polyurethane, thermoplastic polyurethane elastomer, thermoplastic polyurethane vulcanizate, thermoplastic silicone vulcanizate, thermoplastic urethane, thermoplastic urethane elastomer, tetrafluoroethylene/hexafluoropropylene/vinylidenefluoride terpolymer, and combinations thereof. In alternative embodiments, adhesive layers have a curing agent admixed into the polymer of the adhesive layer with optional irradiative treatment.

As noted above, for irradiated composite embodiments, radiation is provided from several alternative radiation sources: any of ultraviolet radiation, infrared radiation, ionizing radiation, electron beam radiation, x-ray radiation, an irradiating plasma, a discharging corona, and a combination of these. A preferred approach is to use electron beam radiation (preferably of from about 0.1 MeRAD to about 40 MeRAD and, more preferably, from about 5 MeRAD to about 20 MeRAD). Electron beam processing is usually effected with an electron accelerator. Individual accelerators are usefully characterized by their energy, power, and type. Low-energy accelerators provide beam energies from about 150 keV to about 2.0 MeV. Medium-energy accelerators provide beam energies from about 2.5 to about 8.0 MeV. High-energy accelerators provide beam energies greater than about 9.0 MeV. Accelerator power is a product of electron energy and beam current. Such powers range from about 5 to about 300 kW. The main types of accelerators are: electrostatic direct-current (DC), electrodynamic DC, radiofrequency (RF) linear accelerators (LINACS), magnetic-induction LINACs, and continuous-wave (CW) machines.

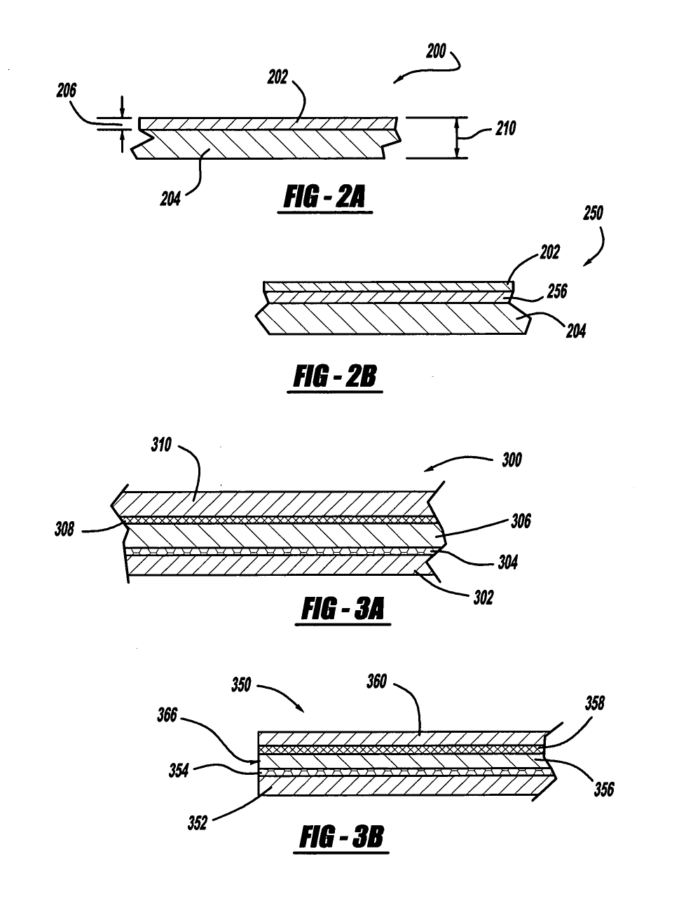

Turning now to details in composite embodiments, FIG. 2A shows a basic composite 200 in cross-section. Fluoropolymeric layer 202 (comprising a multiphase composition of a thermoplastic continuous phase and a fluoroelastomeric amorphous phase as previously described) is cohered to polymeric structural layer 204. FIG. 2B shows composite 250 in cross-section as a modification of composite 200 where polymeric structural layer 204 and fluoropolymeric layer 202 are cohered together in composite 250 with adhesive layer 256.

In various embodiments of the invention, the fluoropolymer layer in composites of the invention is a relatively thin layer, especially when considered as a fraction of the total composite thickness. For clarity, this relation is illustrated in the composite of FIG. 2A; it is to be understood that it is a general feature of other embodiments as well.

In one embodiment, illustrated in FIG. 2A, fluoropolymeric layer 202 has thickness 206 of from about 0.5 of a mil to about 10 mils. In another embodiment, fluoropolymeric layer 202 has fluoropolymeric layer thickness 206, composite 200 has composite thickness 210, and the fluoropolymeric layer thickness 206 has a ratio to composite thickness 210 of from about 1:25 to about 1:250. In yet another embodiment, fluoropolymeric layer 202 has fluoropolymeric layer thickness 206 and comprises a multiphase composition as previously described such that fluoropolymeric layer 202 (and composite 200) has a permeation constant of not greater than 25 gms-mm/m²/day to ASTM D-814 Fuel C gasoline. In yet another embodiment, fluoropolymeric layer 202 has fluoropolymeric layer thickness 206 and comprises a multiphase composition as previously described such that fluoropolymeric layer 202 (and composite 200) has a permeation constant of not greater than 25 gms-mm/m²/day to hydrocarbon distillate compounds having at least seven carbon atoms. It should be noted that the relative thicknesses indicated in the composites of FIGS. 2A, 2B, 3A, 3B, 5A, 5B, 5C, and 10A to 10F are not necessarily to scale and are intended to readily indicate the order of layers in the multilayer structures rather than to rigorously show thicknesses in relative scale.

As noted, in one embodiment, fluoropolymeric layer 202 has thickness 206 of from about 0.5 of a mil to about 10 mils. Therefore, fluoropolymeric layer 202 has thickness 206 of from about 12.5 microns to about 250 microns. With respect to amorphous portions having independent diameters of from about 0.1 microns to about 100 microns in the thermoplastic phase, a layer of 12.5 microns can therefore be formed, in some embodiments, from a multiphase composition having individual amorphous phase particles whose diameter in one dimension prior to forming is 100 microns. In such an embodiment, the larger amorphous portions of the multiphase composition (prior to forming) extend during forming of fluoropolymeric layer 202 to provide non-spherical elongated portions in formed fluoropolymeric layer 202.

FIG. 3A shows composite 300 having a plurality of polymeric structural layers. Fluoropolymeric layer 302 (comprising a multiphase composition of a thermoplastic continuous phase and a fluoroelastomeric amorphous phase as previously described) is cohered to polymeric structural layer 306 with adhesive layer 304. Polymeric structural layer 304 is cohered to polymeric structural layer 310 with adhesive layer 308. A non-limiting example of benefit in this type of composite design is that fluoropolymeric layer 302 can provide chemo-resistant barrier properties (for example, low permeability to gasoline and/or resistance to Bronsted-Lowry bases) to composite 300, structural layer 306 can provide fundamental structural properties to composite 300 respective to tensile and compressive strength, and structural layer 310 can provide a finishing surface for a desired appearance of composite 300.

FIG. 3B shows a cross section view of composite 350 having a first structural layer 352 as a first outside layer, polymeric structural layer 360 as a second outside layer, and fluoropolymeric layer 356 as an internal layer in composite 350, where first outside layer 352 and second outside layer 360 independently cohere to internal layer 356 (fluoropolymeric layer 356). In this regard, layer 352 coheres to layer 356 with benefit of adhesive layer 354, and layer 360 coheres to layer 356 with benefit of adhesive layer 358. Composite 350 thereby provides a mechanical compression spring where the elastomeric character of fluoropolymeric layer 356 provides a robust elastic property to the composite. In this regard, fluoropolymeric layer 356 provides a robust elastic property to the composite as indicated in a compression set value of not greater than 60 for the composite. As a further benefit, fluoropolymeric layer 356 is resistive to “side attack” by either gasoline and/or Bronsted-Lowry (amine) bases. In this regard, for fluoropolymeric layer 356 to impart a compressive spring facility to composite 350, fluoropolymeric layer 356 has an exposed edge surfaces (such as edge surface 366) on the sides of composite 350 generally perpendicular to the plane of composite 350. While the surface area of edge 366 is minor in most embodiments when compared, for example, to the surface area cohering fluoropolymeric layer 356 to layer 358, edge 366 is directly exposed to any fluid with which composite 350 might come into contact. As such, chemo-resistive aspects in fluoropolymeric layer 356 are beneficial in protecting the integrity of composite 350 against detrimental chemical reactions between fluoropolymeric layer 356 and the fluid at edge 366 (and protecting composite 350 thereby against “side attack”).

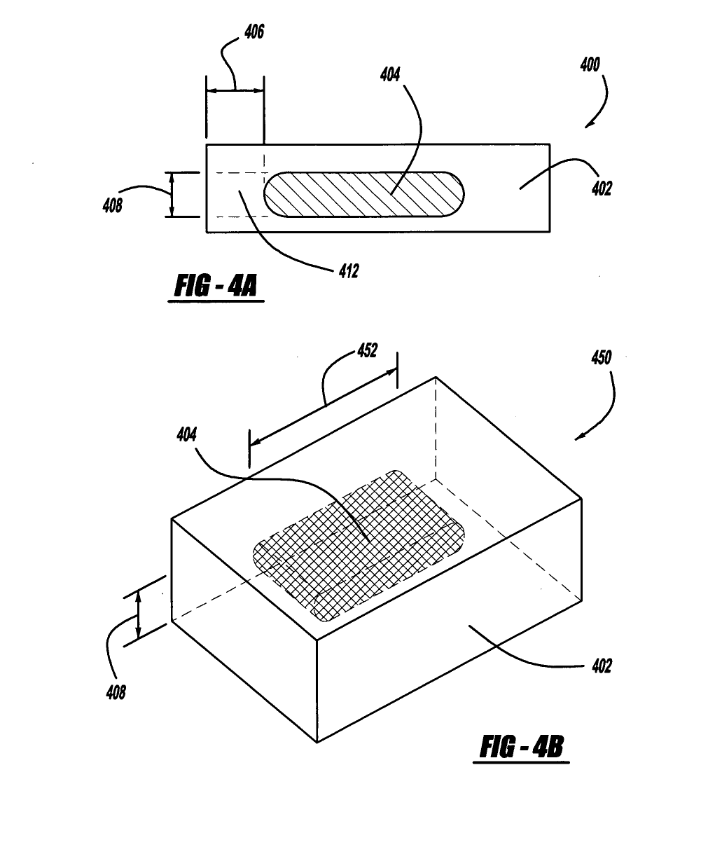

FIG. 4A shows composite 400 having a core 404 of polymer. In one embodiment, core 404 is a structural polymer of composite 400 and encapsulating layer 402 is a fluoropolymeric layer. Such an embodiment, in non-limiting example, benefits from permeability or other chemo-resistant properties in fluoropolymeric encapsulating layer 402 while deriving structural robustness from polymeric structural core layer 404. In an alternative embodiment of composite 400, core 404 is a fluoropolymeric layer and encapsulating layer 402 is a structural polymer layer. Such an embodiment, in non-limiting example, benefits from high temperature robustness in a potentially lightweight fluoropolymeric core 404 while having a non-elastic structural polymer 402 on the outside. Another composite 400 embodiment having a core 404 as a fluoropolymeric layer, in non-limiting example, benefits from high temperature robustness in a potentially lightweight fluoropolymeric core 404 while having structural polymer 402 on the outside selected to readily bond to another component of interest.

When a composite embodiment has core 404 as a fluoropolymeric layer and encapsulating layer 402 is a structural polymer layer, and the composite is used in an application where heat is generated (for example, by friction such as in a dynamic seal application) in encapsulating layer 402, then the relatively low heat transfer coefficient of fluoropolymeric core 404 can impede heat flow within composite 400 and generate thereby a high temperature within the composite if a heat source (such as derived from friction against a surface of the composite) continues to input energy into composite 400. Insofar as fluoropolymeric layer 404 has a decomposition temperature, composite 400 will be detrimentally affected if the internal temperature of composite 400 rises above that decomposition temperature. Accordingly, polymeric structural layer 402 encapsulating fluoropolymeric layer 404 is designed to have a thermal conductivity sufficient for maintaining temperature in fluoropolymeric layer 404 to less than the decomposition temperature of fluoropolymeric layer 404. In this regard, area 412 shows a cross-sectional area within composite 400, with dimensions 406 and 408 showing one cross sectional area available for heat transfer. As should be appreciated, heat fluxes through physical material rather than through an infinitesimally thin geometric plane, so a further cross-section area perpendicular to the plane defined by dimensions 406 and 408 is necessary so that a volume of structural polymer is available for providing thermal conductivity and heat transfer within layer 402 around core 404. Such a perpendicular cross-sectional area has dimensions 408 and 452, with dimension 452 being appreciated from perspective view 450 in FIG. 4B of composite 400. The minimum thermal conductivity for heat transfer (the cross-section of dimension 406 and dimension 408 in conjunction with the cross section of dimension 408 and dimension 452 for a particular structural polymer) within a section of polymer 402 to maintain the temperature within composite 400 (450) below the degradation temperature of core 404 therefore ultimately represents a convolved area product establishing an effective material volume in layer 402 for enabling heat transfer.

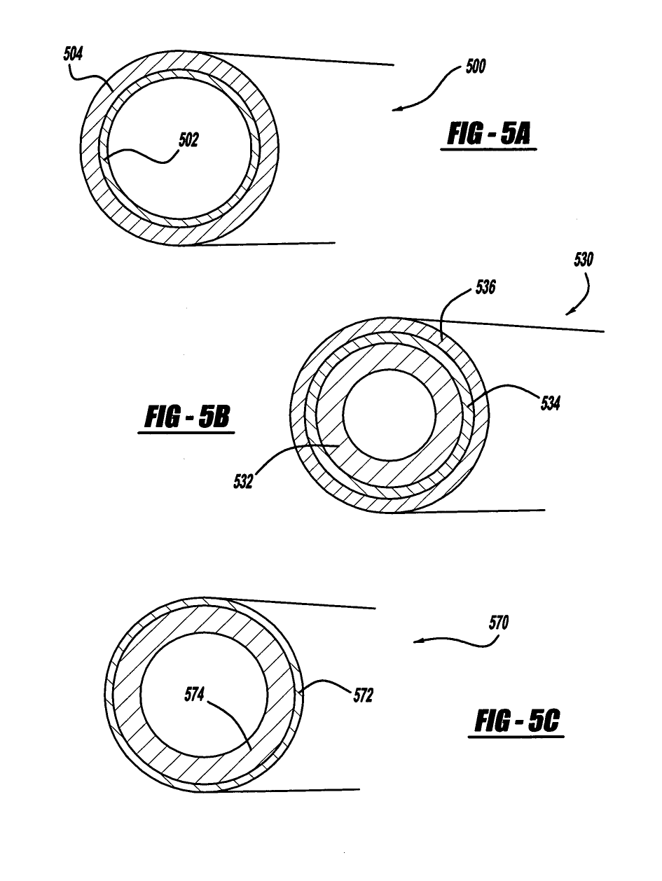

FIG. 5A, FIG. 5B, and FIG. 5C present, in cross-sectional view, three alternative embodiments of composite tubes or hoses incorporating a fluoropolymeric layer. FIG. 5A presents tubular composite 500 (tubular conduit 500) having fluoropolymeric layer 502 as an inner liner and structural polymer 504 as an outer layer cohered to fluoropolymeric layer 502 (optionally with an adhesive layer not shown). When composite 500 is a fuel hose, the preparation of the multiphase composition for fluoropolymeric layer 502 preferably includes dispersing of conductive particulate into the multiphase composition to provide an electrical resistivity of less than about 1×10⁻³ Ohm-m at 20 degrees Celsius in fluoropolymeric layer 502 (through a plurality of conductive particles dispersed in fluoropolymeric layer 502) along with a formulation of the multiphase composition and a sizing of layer 502 to provide a permeation constant of not greater than 25 gms-mm/m²/day to ASTM D-814 Fuel C gasoline through the layers of the fuel hose. In a preferred embodiment of a fuel line according to the general design of composite 500, layer 502 is formulated and dimensioned to provide for a compressive sealing of composite 500 around an essentially rigid tube to which the fuel line of composite 500 is attached (preferably via a compression set value of not greater than 60 in inner layer 502). In use, the fuel hose inner lining (layer 502) is electrically grounded so that static electricity (generated by fuel flowing within the fuel hose) is readily dissipated to maintain the fuel hose at a safe static electrical potential. In an alternative embodiment of a fuel line where, in use, the flow of fuel is insufficient for creating static electrical charge buildup, layer 502 is prepared without benefit of conductive electrical particulate and is sized to provide a permeation constant of not greater than 25 gms-mm/m²/day to ASTM D-814 Fuel C gasoline through the layers of the fuel line. Another embodiment for a flexible composite with the design of composite 500 is in a peristaltic pump flexure tube.

FIG. 5B shows tubular composite 530 having fluoropolymeric layer 534 cohered to inner layer 532 (a first polymeric structural layer) and also to outer layer 536 (a second polymeric structural layer). Fluoropolymeric layer 534 is optionally cohered to either layer 536 and/or layer 532 with independent adhesive layers (not shown, but that should be apparent given the benefit of the foregoing). Such a composite design enables a tube benefiting, for example, from the innate high strength and lightness of fluoropolymer 534 in relatively high temperature service. It should be noted, however, that such a composite design couldn't readily transfer heat at a low temperature differential from layer 532 to layer 536 or from layer 536 to layer 532 for temperature control if layer 534 has a significant thickness unless layer 534 is formulated with filler that promotes heat transfer.

Tubular composite 530 is also a tubular composite having polymeric structural layer 536 as a first external layer, polymeric structural layer 532 as a second external layer for composite 530 (even as layer 532 is an internal lining of the tube of composite 530), and fluoropolymeric layer 534 as an internal layer of the composite, where layer 536 and layer 532 independently cohere to the internal layer (fluoropolymeric layer 534), optionally with benefit of an adhesive layer if needed. In one embodiment, where layer 532 is flexible, composite 530 thereby provides a basis for some degree of mechanical compression spring or extension spring functionality in perpendicular orientation to the centerline of the tube where the elastomeric character of fluoropolymeric layer 534 provides a robust elastic property to the composite and inner layer 532 can be either compressed or tensioned respective to the centerline of the tube.

FIG. 5C shows tubular composite 570 with fluoropolymeric layer 572 as an outside layer and polymeric structural layer 574 as an inner lining. Such a composite is essentially a structural inverse of composite 500 with respect to properties of the layers. Accordingly, composite 570 provides a polymeric tube that, in non-limiting example, finds use for a tube immersed within a fuel or a material such as an amine base.

Composites according to the general designs of any of composite 200, composite 250, composite 300, composite 350, composite 400, composite 500, composite 530, and composite 570 have many uses. The ability to form a finely dimensioned fluoropolymeric layer having high chemo-resistive properties and also low compression set properties brings forward a preferred use of the above composite embodiments in items such as (in non-limiting example) gaskets, dynamic seals, packing (static) seals, o-rings, pump diaphragms, and peristaltic pump flexure tubes. The invention thereby enables both new composite constructions of these sealant articles as well as new assemblies incorporating such new composite sealant articles.

In one embodiment, a new assembly is derived from a traditional assembly with the straightforward replacement of a prior seal (such as an o-ring) with a new multilayer o-ring according to the invention. In another embodiment, a new assembly is derived from a replacement of a prior seal (such as an o-ring) with a new multilayer seal of the same external dimensions along with further re-design (from the assembly's original design prior to the use of the composite seal according the invention) to take advantage of the performance properties enabled in the seal by the invention. In this regard, in non-limiting example, an improved thermal stress capability in a composite seal having a fluoropolymeric layer according to the invention enables one assembly to operate at a higher operating temperature after the prior seal has been replaced with a new multilayer seal according to the invention. The higher operating temperature enables more efficacious heat transfer from the system to its respective heat sink, and the assembly is accordingly then beneficially redesigned to have a smaller heat transfer area (such as provided by a radiator).

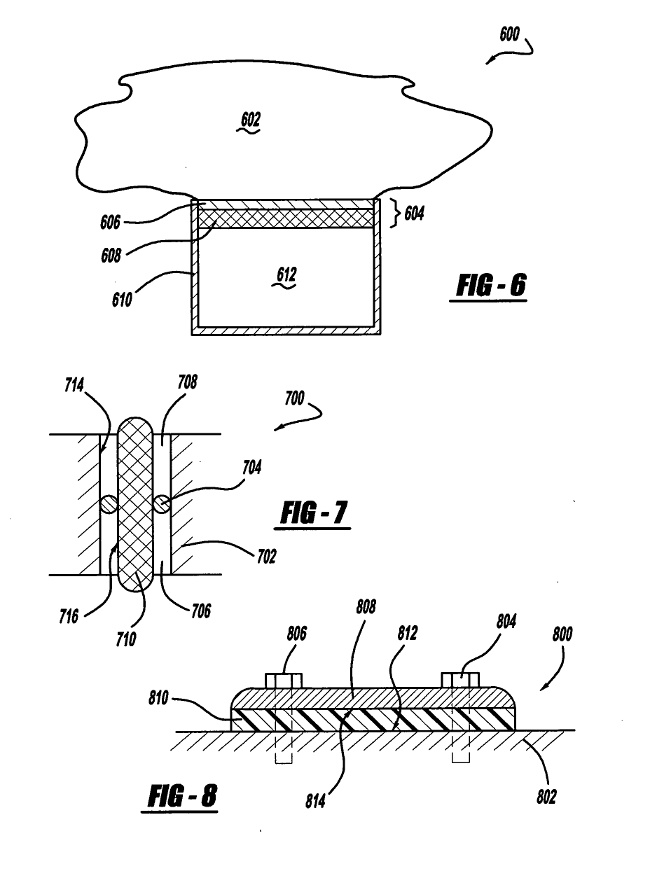

Turning now to specifics in assemblies using the multilayer seals of the invention, FIG. 6 shows a general sealed assembly model 600. Object 610 has internal space 612 defined within object 610, and space 612 is essentially isolated from fluid 602 with a barrier either capable of flexing and/or capable of being periodically removed and/or opened. Seal 604 provides such a barrier as a multilayer seal having barrier layer 606 and structural polymer layer 608. Barrier layer 606 is a fluoropolymeric layer comprising a multiphase composition as previously described herein; layer 606 is cohered to layer 608 to provide a composite as barrier (seal) 604 across the entrance to space 612. Fluid 602 is broadly defined and includes any liquid, gas, dispersion of a gas and a liquid, dispersion of liquid vapor in a gas, dispersion of solid particulate in a liquid, and dispersion of solid particulate in a gas. In this regard, in non-limiting example, fluid 602 in one embodiment is a dispersion of solid particulate in a gas provided in the form of air with a low concentration of dust particles. In another non-limiting example embodiment, fluid 602 is a dispersion of solid particulate in a liquid provided in the form of oil with a low concentration of suspended metal particles. In yet another non-limiting example embodiment, fluid 602 is a liquid provided in the form of gasoline. In still another non-limiting example embodiment, fluid 602 is a gas provided in the form of air at a first pressure where space 612 is filled with air at a second pressure different from the first pressure.

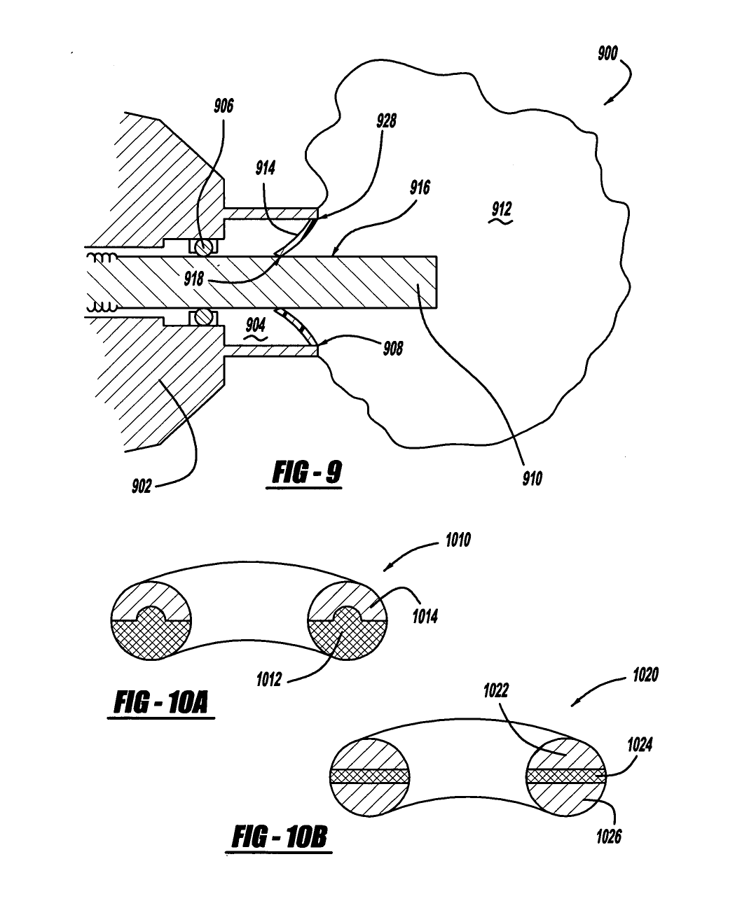

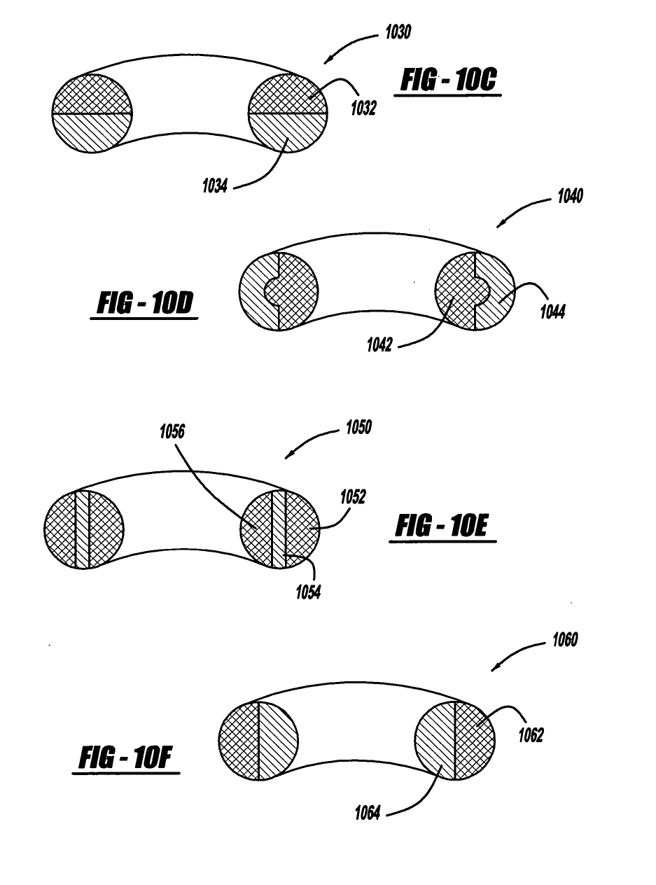

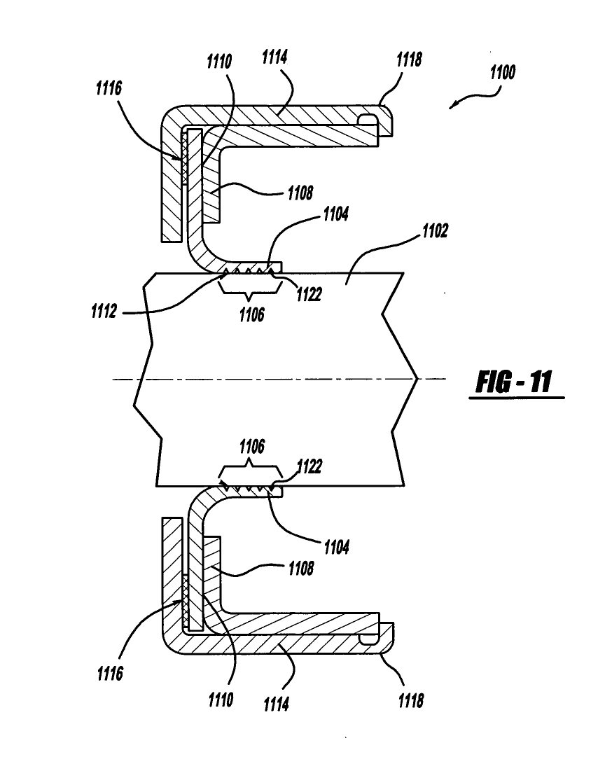

One embodiment of a sealed assembly sealed with a packing seal is depicted in FIG. 7 in mechanical assembly cutaway 700 where first component 702 has rigid surface 714 and second component 710 has rigid surface 716. Seal 704 (a composite packing article also denoted as a static seal or as a multilayer packing seal having a fluoropolymeric layer as described above where the term packing seal denotes a deformable assembly component compressed or adapted to be compressed to some degree between at least two surfaces to prevent or control leakage of fluid between surfaces that either move or are essentially capable of moving in relation to each other including, without limitation, any article from application product categories termed as gaskets, rings, seals, packing, stuff, gland packing, stuffing, stopping, wadding, padding, joining sheet, thread tapes, and winding tapes) is disposed between rigid surface 714 and rigid surface 716 to seal (essentially isolate) any fluid within space 708 from any fluid in space 706. In one embodiment of space 706 (shown in cutaway), surface 714 defines a circular bore within component 702 and component 710 is a cylindrical object fitting within the circular bore with cylindrical surface 716 being sealed against cylindrical surface 714 with (an o-ring) seal 704. Seal 704 is a composite according to, in non-limiting example, the general layer arrangement of any of composite 200, composite 250, composite 300, composite 350, or composite 400, or an o-ring composite according to any of o-rings 1010, 1020, 1030, 1040, 1050, or 1060 as presented in FIGS. 10A to 10F further herein. In one embodiment, the multilayer seal bears lightly against surfaces 716 and 714 and is thereby slideably disposed between surface 714 and surface 716 so that component 710 can be moved in parallel with the axis of the bore within component 702. In an alternative embodiment, the multilayer seal bears tightly between surfaces 716 and 714 and is thereby compressively disposed between surface 714 and surface 716 so that component 710 essentially cannot be moved along the axis of the bore within component 702.

FIG. 8 shows another embodiment of a sealed assembly in mechanical assembly cutaway 800 where a first component 802 has rigid surface 812 and a second component 808 has rigid surface 814. Seal 810 (a composite packing article also denoted as a static seal or as a multilayer packing seal having a fluoropolymeric layer as described above) is disposed between rigid surface 814 and rigid surface 812 to seal (essentially isolate) any fluid from passage through the space filled by seal 810. Seal 810 is a composite according to, in non-limiting example, the general designs of any of composite 200, composite 250, composite 300, composite 350, and composite 400. Multilayer seal 810 bears tightly between surfaces 812 and 814 and is thereby compressively disposed between surface 814 and surface 812. For example, Seal 810 is compressed through forces derived from bolt 804 and bolt 806. As should be apparent, one embodiment of composite 810 is a head gasket for an internal combustion engine. Another embodiment of composite 810 is an oil pan gasket for an internal combustion engine. Another embodiment of composite 810 is a gasket for an automatic transmission. Another embodiment of composite 810 is a gasket for a manual transmission.

FIG. 9 shows another embodiment of a sealed assembly in mechanical assembly cutaway 900 where component 910 is in one form of pivoting connection to base 902 with pivoting of component 910 augmented by roller bearing 906. In this regard, pivoting references movement by a component respective to a base to which it is mechanically adjoined or restrained and includes, without limitation, movement relative to the base termed as any of swinging, rotating, rotating about an axis, oscillating, turning, spinning, swiveling, screwing, sliding, and wheeling. Flexible multilayer seal 914 (a composite article also denoted as a dynamic seal or as a multilayer torsion seal having a fluoropolymeric layer as described above) is disposed in contact with fluid 912 and also with a sealing surface of component 910 (the sealing surface of component 910 is the surface 916 of component 910 in the general area of location 918). Component 910 thereby has a first portion in contact with fluid 912 (that portion of component 910 generally to the right side of location 918 in FIG. 9), a second portion isolated from contact with fluid 912 (that portion of component 910 generally to the left side of location 918 in FIG. 9), and a sealing surface (surface 916 of component 910 essentially at location 918) interfacing the first and second portions of component 910. Flexible multilayer seal 914 has a surface portion (a first edge) fixedly sealed to base 902 as depicted at cutaway locations 908 and 928.

Flexible multilayer seal 914 has a surface portion (a second edge) configured or adapted to compressively fit against the sealing surface of component 910 (surface 916 of component 910 essentially at location 918). In one embodiment, the first and second surface portions are independent edges; in an alternative embodiment not shown, a single continuous edge is separated into the two edge portions to provide the first and second surface portions. The sealed edges (or edge surface portions) essentially enable a full sealing of seal 914 fixedly to base 902 and compressively (slideably or statically) against the sealing surface of component 910 so that fluid 912 essentially cannot fluidly flow to space 904.

In this regard, flexible multilayer seal 914 is torsionally flexed (deflected as if to initiate the first winding of a torsion spring) to (sealingly) bear its second surface portion against the sealing surface of component 910 so that the second portion of component 910 is essentially isolated from the fluid within cove space 904 (a relatively small protected and/or sheltered space or nook) defined between base 902 and flexible multilayer seal 914. All surfaces of component 910, base 902, roller bearing 906, and flexible multilayer seal which define cove space 904 therefore establish a section of the mechanical assembly that is essentially isolated from fluid 912.

In one embodiment, an air or nitrogen purge (not shown) maintains a positive pressure (respective to the pressure of fluid 912) within cove space 904 so that bearing 906 and the sealing surface of component 910 are further isolated from contaminants of concern in fluid 912. In one embodiment, the second surface portion statically bears against the sealing surface of component 910, and component 910 is only occasionally pivoted; in an alternative embodiment, component 910 is frequently pivoted (rotated about its axis) respective to base 902. One embodiment of composite 914 is a dynamic seal for an automobile crankcase. Another embodiment of composite 914 is a protective boot for a removable threaded measurement probe. In one embodiment, cove 904 contains lubricating oil.

As should be appreciated from a consideration of FIGS. 7, 8, and 9, seals in one context are usefully, but not exclusively, designated into two important types respective to application utility as either being static (frequently as packing) type seals or as dynamic (frequently as flexible or torsion) type seals. In this regard, a “static seal” designation generally references a seal that, in use, packs between two surfaces to fill and essentially seal the intervening space between the two surfaces where the seal is under some degree of compression from the two surfaces.

In a static seal, most spring functionality derives from the compression set properties of the seal, so a static seal is usually mechanically modeled as a compression spring (or, if extended, as an extension spring). While one surface sealed by the seal may move respective to the other surface sealed by the seal, such movement usually tends to be either occasional or relatively minor in degree so that the amount of linear travel of either surface against the static seal does not generate appreciable friction or attendant heat for the static seal to transmit and/or absorb.

In one embodiment, a method of sealing an assembly (having a first component having a first rigid surface, and a second component having a second rigid surface) is provided of (a) cohering at least one polymeric structural layer to a fluoropolymeric layer to make a multilayer packing seal according the above composite design and (b) disposing the multilayer packing seal between the first rigid surface and the second rigid surface to establish a seal between the two components in the assembly. The composite is further irradiated in one embodiment alternative. In one assembly embodiment, the seal is slidably disposed between the two surfaces under gentle compression, and in another assembly embodiment, the seal is aggressively compressed between the two surfaces. In various embodiments of the methods, the cohering step uses any of compression molding, injection molding, extrusion, transfer molding, and insert molding techniques.

A “torsion seal” or designation herein generally references a seal that, in use, usually closes an open space between two surfaces to essentially seal the intervening space or area between a movable surface and a non-movable surface through flexing as a torsion spring under tension to bear against the movable surface with an edge designed to manage a reasonable amount of movement of the movable surface against the seal edge interfacing to the movable surface. In this regard, the seal edge interfacing to the movable surface frequently manages appreciable friction or attendant heat either transmitted to or absorbed by the torsion seal. A flexible seal of this type achieves its torsion spring functionality primarily by use of its object tensile properties, although compression set properties may augment the overall torsion spring functionality with some compression spring aspects at the interfacing edge between the seal and the moving surface. Torsion seals provide a type of dynamic seal construction (dynamic seals traditionally generally including oil seals, hydraulic and pneumatic seals, exclusion seals, labyrinth seals, bearing isolators, piston rings, and back-up rings).

In one embodiment, a method of sealing an assembly (according to the above description) to isolate a section of the assembly from contact with a fluid is provided. The method includes
(a) cohering of at least one polymeric structural layer to a fluoropolymeric layer (comprising a continuous thermoplastic phase and a dispersed fluoroelastomeric amorphous phase as describe above) to make a flexible multilayer torsion seal having a first sealing surface portion and a second sealing surface portion where the second sealing surface portion is adapted to compressively fit against the sealing surface;
(b) fixedly sealing the first sealing surface portion to the base; and
(c) torsionally flexing the flexible multilayer torsion seal to sealingly bear the second sealing surface portion against the sealing surface such that the first component portion is essentially isolated from the fluid within a cove space defined between the base and the flexed flexible multilayer torsion seal.

The flexible multilayer torsion seal is further irradiated in one embodiment with radiation. In another embodiment, the method further includes incising a continuous groove into the second sealing surface portion so that a channel is provided for fluidly conveying lubricant to the cove space through viscous interaction of the lubricant with the dynamic sealing surface. In another embodiment, the cohering is achieved by cohering an adhesive layer to the fluoropolymeric layer and then cohering the adhesive layer to one of the polymeric structural layers. In an embodiment where the base further comprises a housing and a removable flange adapted for tightly and sealingly attaching to the housing, the fixedly sealing operation seals the first sealing surface portion to the flange. In one embodiment of this, the housing has a spring-form end portion adapted for tightly clipping the flange to the housing, and the torsionally flexing is achieved in the process of clipping the flange to the housing while, at the same time, bearing the second surface portion against the sealing surface of the pivotable component. In various embodiments, the cohering is done through use of any of compression molding, injection molding, extrusion, transfer molding, and insert molding processes.

While designations such as “compression seal”, “torsion seal”, “static seal”, “packing seal, “dynamic seal”, and “flexible seal” are useful for discussing seal features in an application context, the designations are neither rigorously unique or exclusive to the types of surface and intervening space situations that are sealed. In some embodiments, the packing type of seal (with, for instance, the benefit of substantial lubrication) usefully interfaces to a movable surface—a packed pump is one example of such a situation where a packing seal is slideably disposed against a very dynamic surface. In other embodiments, the flexible (dynamic type) torsion seal interfaces between two surfaces that have essentially no relative movement—a protective boot on a pivotally removable measurement probe where one end of the probe protrudes through the boot is one example of such a situation where a flexible seal, except for an occasional execution of removal of the probe, is essentially statically disposed between the two surfaces defining the area being sealed.

As previously noted, a very thin (for example, 0.5 mil) fluoropolymeric layer is enabled in a composite when the fluoropolymeric layer comprises a multiphase composition having a continuous phase of a thermoplastic polymer material and a fluoroelastomeric amorphous phase dispersed in the continuous phase in independent portions having independent diameters of from about 0.1 microns to about 100 microns. This feature enables new geometrically complex gaskets and seals to be manufactured as shaped articles. As previously noted, in planar (or essentially flat surface) seals, this feature enables a composite to have a very thin barrier layer. In other seals, such as o-rings, the geometric flexibility provides a substantial degree of freedom for enabling new and highly functional seals. In this regard, FIGS. 10A to 10F depict a number of alternative multilayer o-ring seal configurations with each configuration having a fluoropolymeric layer as previously described herein.

Turning to an o-ring embodiment profiled in cross section in FIG. 10A, o-ring 1010 has structural polymer layer 1012 cohered to fluoropolymeric layer 1014, optionally with an adhesive layer not shown. Fluoropolymeric layer 1014 has a modified fluoropolymeric semicircular cross-sectional area. The diametric chord subtending the semicircle is positioned essentially horizontal to the plane of o-ring 1010 (the plane of an o-ring being the plane containing the entire curvilinear axis of the o-ring). A further semi-circularly inscribed cross-sectional portion of structural polymer layer 1012 is imposed inside the semicircle of fluoropolymeric layer 1014. The arc length of the imposed semicircle is co-centrically radially parallel to the arc length of the fluoropolymeric semicircular cross-sectional area. The subtending diametric chord for the arc length of the imposed semicircle is also positioned essentially horizontal to the plane of o-ring 1010. The vertex and chord sides of the supplementary angle (establishing the diametric chord) for the arc length of the inscribed cross-sectional area are superimposed onto the vertex and chord sides of the supplementary angle (establishing the diametric chord) of the arc length subtending the fluoropolymeric semicircular cross-sectional area. This configuration enables structural polymer layer 1012 to have a significantly centered presence in o-ring 1010 respective to the circular curvilinear axis of o-ring 1010 and enables fluoropolymeric layer 1014 to have an essentially consistent thickness for compression in use from forces applied in essentially perpendicular orientation to the plane of o-ring 1012. O-ring 1010 therefore should provide especial benefits in bearing of heavy loads.

FIG. 10B presents a cross section profile for o-ring 1020 with fluoropolymeric layer 1024 independently cohered to structural polymer layer 1022 and to structural polymer layer 1026, optionally with adhesive layers not shown. Fluoropolymeric layer 1024 is essentially horizontally positioned respective to the plane of the o-ring as an internal layer in the o-ring. This configuration enables structural polymer layers 1022 and 1026 to interface directly with surfaces above and below the plane of o-ring 1020 and enables fluoropolymeric layer 1024 to provide mechanical compression spring functionality within o-ring 1020 for forces essentially applied perpendicularly to the plane of o-ring 1020.

FIG. 10C presents a cross section profile for o-ring 1030 with fluoropolymeric layer 1034 cohered to structural polymer layer 1032, optionally with an adhesive layer not shown. Fluoropolymeric layer 1034 has a semicircular cross-sectional area in o-ring 1030. The semicircle is subtended by a diametric chord that is essentially horizontally positioned respective to the plane of the o-ring so that fluoropolymeric layer 1034 provides an elastic barrier layer for one surface compressed with a force that is essentially perpendicular to the plane of o-ring 1030 and where a barrier to chemical attack is needed on one side of o-ring 1030. An o-ring for use in a valve stem is a non-limiting example of an application use.

FIG. 10D presents a cross section profile for o-ring 1040 configured substantially according to the detail of o-ring 1010 but with the fluoropolymeric layer 1044 having a repositioned fluoropolymeric semicircular cross-sectional area in o-ring 1040. Fluoropolymeric layer 1044 has a modified fluoropolymeric semicircular cross-sectional area. The diametric chord subtending the semicircle is positioned essentially perpendicular to the plane of o-ring 1040. A further semi-circularly inscribed cross-sectional portion of structural polymer layer 1042 is imposed inside the semicircle of fluoropolymeric layer 1044. The arc length of the imposed semicircle is co-centrically radially parallel to the arc length of the fluoropolymeric semicircular cross-sectional area. The subtending diametric chord for the arc length of the imposed semicircle is also positioned essentially perpendicular to the plane of o-ring 1040. The vertex and chord sides of the supplementary angle (establishing the diametric chord) for the arc length of the inscribed cross-sectional area are superimposed onto the vertex and chord sides of the supplementary angle (establishing the diametric chord) of the arc length subtending the fluoropolymeric semicircular cross-sectional area. This configuration enables structural polymer layer 1042 to have a significantly centered presence in o-ring 1040 respective to the circular axis of o-ring 1040 and enables fluoropolymeric layer 1044 to have an essentially consistent thickness for compression in use from forces that are essentially radially-applied outward toward the center of o-ring 1040 in horizontal orientation to the plane of o-ring 1040. An example of application is for a tightly compressed seal in corrosive service, such as a seal for a measuring probe positioned on the exterior of a ship.

As should be appreciated from a consideration of FIG. 10D, a further embodiment of an o-ring with a similarly shaped fluoropolymeric layer inverted by 180 degrees to be positioned on the inside diameter portion of an o-ring provides a multilayer o-ring enabling a fluoropolymeric layer to have an essentially consistent thickness for compression in use from forces essentially applied away from the center of the o-ring in horizontal orientation to the plane of the o-ring. A seal on the upper rim of a liquid cell battery where pressurization might occur is one example of an application.

FIG. 10E presents a cross section profile for o-ring 1050 configured substantially according to the detail of o-ring 1020 of FIG. 10B but with fluoropolymeric layer 1054 repositioned to be independently cohered to structural polymer layer 1052 and to structural polymer layer 1025, optionally with adhesive layers not shown. Fluoropolymeric layer 1054 is positioned essentially perpendicular to the plane of o-ring 1050 as an internal layer in the o-ring composite. This configuration enables structural polymer layers 1052 and 1056 to interface directly with surfaces essentially perpendicular to the plane of o-ring 1050 and enables fluoropolymeric layer 1054 to provide mechanical compression spring functionality within o-ring 1050 for essentially radially applied forces that are horizontal to the plane of o-ring 1050. An o-ring for sealing a radially compressed can lid to the upper side of a jar is an example of an application.

FIG. 10F presents a cross section profile for o-ring 1060 configured substantially according to the detail of o-ring 1030 in FIG. 10C but with fluoropolymeric layer 1064 repositioned to be cohered to structural polymer layer 1062 (optionally with an adhesive layer not shown) with a semicircular cross-sectional area in o-ring 1060. The diametric chord that subtends the semicircle is positioned essentially perpendicular to the plane of the o-ring. In this configuration, fluoropolymeric layer 1064 provides an elastic barrier layer for one surface compressed with from an essentially radially-applied force applied horizontally to the plane of o-ring 1060 outwardly from within the inner diameter of o-ring 1060.

As should be appreciated from a consideration of FIG. 10F, a further embodiment of an o-ring with a similarly shaped fluoropolymeric layer inverted by 180 degrees to be positioned on the outside diameter portion of an o-ring provides a multilayer o-ring enabling a fluoropolymeric layer to have an essentially consistent thickness for compression in use from forces essentially applied toward the center of the o-ring in horizontal orientation to the plane of the o-ring.

Turning now to FIG. 11, seal detail for a dynamic seal for an automobile crankshaft is presented in sealed assembly 1100 benefiting from a flexible multilayer seal similar to seal 914 in FIG. 9. Shaft 1102 is sealed with flexible multilayer seal 1104 at a sealing surface portion of shaft 1102 indicated at location 1106. Flexible multilayer seal 1104 has surface portion 1110 fixedly sealed to connecting flange 1108. Surface portion 1112 is shaped to seal against shaft 1102 at location 1106 by slideably bearing against shaft 1102. Housing 1114 has a spring-form end portion 1118 (establishing a torsion spring) for tightly clipping flange 1108 against sealing washer 1116 to compress sealing washer 1116 between seal 1104 and housing 1114 with opposing spring forces from sealing washer 1116 and spring-form end portion 1118 sustaining flange 1108 in connection to housing 1114. In this regard, seal 1104 and flange 1108 are therefore, in one embodiment, initially constructed as an independent assembly and clipped into position within assembly 1100. Flexible multilayer seal 1104 is torsionally flexed to (sealingly) bear surface portion 1112 against the sealing surface (location 1106) of shaft 1102. Groove cross-sections 1122 are cut into seal 1104 to retain micro-reservoirs of lubricant. In this regard, groove cross-sections 1122 in one embodiment show cross-sectional profiles from a continuous unified groove or channel incised into seal 1104 either as a spiral groove around a circular interfacing surface portion or, in an alternative embodiment, as a switchback pattern to provide thereby a channel for fluidly conveying lubricant in the channel from momentum conveyed into the lubricant through viscous interaction with pivoting shaft 1102.

Methods of mixing and/or dynamic vulcanization to disperse a fluoroelastomeric amorphous phase into a thermoplastic continuous phase to provide a multiphase composition have been previously described herein. The multiphase composition is then used in the embodiments to make a fluoropolymeric layer in a composite. In this regard, the composite is made by a method of generating a polymeric structural layer, and then by cohering the fluoropolymeric layer to the polymeric structural layer to form the composite, where the fluoropolymeric layer comprises the multiphase composition. A further optional step in making a composite is that, after a composite has been formed, the composite can be treated with radiation to achieve any of cross-linking between thermoplastic molecules, cross-binding of thermoplastic molecules to fluoroelastomer molecules, or further adhesion between layers in the composite. In this regard, exposure of the composite to electron beam radiation of from about 0.1 MeRAD to about 40 MeRAD is a preferable method of such irradiative treatment. Such treatment can therefore enhance a number of properties in the composite layers, including molecular network structure, cross-linking within and between phases and/or layers, bonding, tensile properties, wear properties, compression set, service temperature, heat deflection temperature, dynamic fatigue resistance, fluid and chemical resistance (chemo-resistivity), creep resistance, dimensional stability, and toughness.

The generating of the structural polymer layer in some method embodiments is preliminary to the generation of the fluoropolymeric layer. In one embodiment, the structural polymer layer is generated by conventional means and hardened and then the fluoropolymeric layer is pultruded onto the structural polymer layer. In another embodiment, the structural polymer layer is molded by conventional means and then the fluoropolymeric layer is added before the structural polymer layer has hardened, and both layers harden simultaneously. In another embodiment, an adhesive layer is added prior to addition of the fluoropolymeric layer. In yet another embodiment, a structural polymer layer is generated by conventional means, a fluoropolymeric layer is cohered to the structural polymer layer, and a second structural polymer layer is added to the fluoropolymeric layer.

In one embodiment, a mandrel is made, the fluoropolymeric layer and the polymeric structural layer are pultruded onto the mandrel, and the mandrel is removed to leave a tubular composite as a residual item.

In further detail of this, a mandrel is extruded and cooled in a water bath in a vacuum sizing system to define the inner dimension of a desired tube. A (first) pultrusion is then performed using the mandrel as a pultrusion core component. In the pultrusion, a multiphase fluoroelastomer gum and thermoplastic blend are fed from an extruder as a first feed stream and ETFE thermoplastic is fed from a second extruder as a second feed stream into a pultrusion die. The pultrusion die and extruders are configured and operated to provide output from the pultrusion die of a 3-layer tube having the mandrel as an inner layer, a thin fluoropolymeric layer of the multiphase blend as a fluoropolymeric layer cohered to the outside surface of the inner layer, and an outer layer of ETFE thermoplastic cohered to the outside surface of the fluoropolymeric layer. The resultant 3-layer pultruded tube is air cooled to solidify the two layers pultruded onto the mandrel. The cooled 3-layer tube is then irradiated on the outer surface with a corona discharge to activate the surface of the outside ETFE layer. The surface treated 3-layer multilayer tube is then input as a pultrusion core component to a second pultrusion die. A third extruder feeds a structural polymer into the second pultrusion die. The pultrusion die and third extruder are configured and operated to provide output from the pultrusion die of a 4-layer pultruded tube that is cooled after exit from the die to decrease the temperature of the outer layer to room temperature. The mandrel is then removed from the 4-layer tube to provide a residual 3-layer tube having the fluoropolymeric layer as the inside layer. The 3-layer tube is then optionally treated with an electron beam to cure (crosslink) the fluoroelastomer in the fluoropolymeric layer, to crosslink thermoplastic material in the fluoropolymeric layer, to promote adhesion between the layers at the layer interfaces, and/or to crosslink polymer chains in structural polymer layers of the composite tube.

Some composite embodiments are made through the process of transfer molding. In a first step of this, a quantity of polymer or uncured rubber is placed into an entry chamber of a mold. The mold is closed and the quantity of polymer or uncured rubber is forced by hydraulic pressure (usually through use of a plunger) into the mold cavity. The molded polymer or uncured rubber is then solidified in the mold cavity under pressure so that the shape of the molded part is stabilized. The plunger is then released, the mold is opened, and the part can be removed. In one method embodiment, applicable for any of o-rings 1010, 1020, 1030, 1040, 1050, and 1060, a first transfer molding of a first layer of the multilayer o-ring is made and cooled in a mold having a first cavity plate and a second cavity plate. The second cavity plate is removed and a third cavity plate then positioned on the first cavity plate (containing the first layer of the o-ring) to provide a cavity for a second transfer molding. The second layer of the multilayer o-ring is then transfer molded onto the first layer. The process is repeated with cavity plates providing additionally sized cavities until the composite has been fully formed. The formed composite is then optionally treated with electron beam radiation to provide the finished composite o-ring.

Insert molding is used for making composites having an encapsulated layer. The layer to be encapsulated (structural polymer or fluoroelastomeric multiphase composition according to the invention) is first made, for example, by injection molding. The layer to be encapsulated is then placed as an insert core into a mold cavity for the insert molding procedure. Plastic (structural polymer or fluoroelastomeric multiphase composition according to the invention) is then injected into the mold cavity around the insert core. The resulting composite has an encapsulated core layer of the injection molded initial layer.

The composites are therefore made by a number of established processes including any of pultrusion, compression molding, multi-layer extrusion, injection molding, transfer molding, and insert molding. In one embodiment, the generating and cohering take place in a mold designed to encapsulate the fluoropolymeric layer within the polymeric structural layer. In another embodiment, the generating and cohering take place in a mold designed to encapsulate the polymeric structural layer within the fluoropolymeric layer.

FKM-TPV materials may be formed into very thin layers of less than about 3 mils in composites using established processes of compression molding, injection molding, transfer molding, and insert molding. For extrusions, a preferred method embodiment for providing a very thin layer of less than 3 mils of multiphase cured fluoroelastomeric (as an amorphous phase) and thermoplastic (as a continuous phase) in a composite is to first extrude a thin layer of a multiphase fluoroelastomer gum and thermoplastic blend (such as in the above-described multi-pultrusion approach) into a formed composite, and then to cure the composite after it has been formed in order to cure the fluoroelastomer gum into cured fluoroelastomer.

Once a packing seal or torsion seal according to the previous description has been made for sealing use in a mechanical assembly, it can then be deployed to complete the machine for which it was designed. In summary of this, one method for sealing an assembly having a first component having a first rigid surface and a second component having a second rigid surface is achieved through disposing a multilayer packing seal according to the composite design for a packing seal of the invention between the first rigid surface and the second rigid surface. Another method seals an assembly with a base and a connected pivoting component by isolating a section of the assembly containing a portion of the pivoting component from contact with a fluid by disposing a flexible multilayer torsion seal according to the composite design for a torsion seal of the invention into the assembly to help to define a cove space around the component portion. In addition to the portion to be isolated from the fluid, the component is designed to have a second component portion exposed to the fluid and a sealing surface interfacing the first component portion (the portion to be isolated) and the second component portion. The torsion seal has a first sealing surface portion adapted for fixedly sealing the flexible multilayer torsion seal to the base, and a second sealing surface portion adapted to compressively fit against the sealing surface. When the seal is disposed into the assembly, the first sealing surface portion is fixedly sealed to the base, and the torsion seal is torsionally flexed to sealingly bear the second sealing surface portion against the sealing surface so that the cove space is defined between the base, the first component portion, and the flexed torsion seal. In one form of this, as described with respect to FIG. 11, the base of a mechanical assembly is enabled with a housing and a flange having complimentary designs for clipping together in a fastening joint; and the flange and torsion seal are provided as a pre-assembled seal assembly for clip-in disposition into the housing of the mechanical assembly being sealed.

### EXAMPLES

### Example 1

Five fluoroelastomer formulations are prepared for comparative fuel permeability properties from a fluoroelastomer gum. A first fluoroelastomer sample is prepared to provide a first control (Control 1) of peroxide cured fluoroelastomer rubber (FKM rubber) in the form of a test object as defined in ASTM D-814. A second fluoroelastomer sample is prepared to provide a second control (Control 2) of bisphenol cured fluoroelastomer rubber (FKM rubber) in the form of a test object as defined in ASTM D-814. A third fluoroelastomer sample (Sample A) is prepared by dynamically vulcanizing the fluoroelastomer gum and polyvinylidene fluoride thermoplastic in a ratio of 2:1 (fluoroelastomer to thermoplastic by weight) using bisphenol as a curing agent, and then Sample A is formed into a test object as defined in ASTM D-814. A fourth fluoroelastomer sample (Sample B) is prepared by dynamically vulcanizing the fluoroelastomer gum and polyvinylidene fluoride in a ratio of 2:1 (fluoroelastomer to thermoplastic by weight) using peroxide as a curing agent, and then Sample B is formed into a test object as defined in ASTM D-814. A fifth fluoroelastomer sample (Sample C) is prepared by intermixing the fluoroelastomer gum and polyvinylidene fluoride in a ratio of 2:1 (fluoroelastomer to thermoplastic by weight), and then Sample C is formed into a test object as defined in ASTM D-814. Each of the five prepared sample objects are evaluated for permeability to ASTM D814Fuel C gasoline in accordance with ASTM D814testing procedures.

Results of the test are indicated in Table 1:

TABLE 1
ASTM D-814 Fuel Permeability For FKM-TPV and
FKM-gum/Thermoplastic Blends In Thin Films

| | | Permeation | |
|---|---|---|---|
| | Permeation | Constant | Relative |
| | Rate | (gms-mm/ | Qualitative |
| | (gms/m²/day) | m²/day) | Porosity |
| Sample A - | 7 | 7 | High |
| 1 mm thickness | | | |
| (FKM-TPV | | | |
| bisphenol cure) | | | |
| Sample B - | 2 | 2 | Low |
| 1 mm thickness | | | |
| (FKM-TPV | | | |
| peroxide cure) | | | |
| Sample C - | 0˜0.4 | 0˜0.8 | None |
| 2 mm thickness | | | Observed |
| (FKM gum/ | | | |
| thermoplastic) | | | |
| Control 1 - | 3 | 6 | High |
| 2 mm thickness | | | |
| (FKM rubber - | | | |
| peroxide cure) | | | |
| Control 2 - | 18 | 18 | Very High |
| 1 mm thickness | | | |
| (FKM rubber - | | | |
| bisphenol cure) | | | |

Fluoroelastomer and polyvinylidene fluoride thermoplastic are used in the Example insofar as fluorinated molecules generally provide good permeability resistance to fuels. In this regard, however, it is also to be noted that fuel should permeate through a cured amorphous fluoropolymer (such as fluoroelastomer) more readily than through a theoretical crystalline equivalent fluoropolymer respective to both a greater intermolecular free volume in the amorphous fluoropolymer and also respective to porosity from voids derived in the elastomer curing process. In this regard, many of the voids in elastomers are generated from very small bubbles of gas produced at site-specific crosslinking reactions during curing within the polymer melt. In comparing the permeation constant between Controls 1 and 2 and also between either of Controls 1 or 2 and Samples A and B, qualitatively inspected porosity of the test objects indicates that gasoline permeability significantly improves as porosity (presence of “bubbles” in the test object) decreases and that curing induced porosity is perhaps therefore significant in fuel permeability properties of fluoroelastomer formulations. In this regard, Sample B demonstrates lower qualitative porosity than either Sample A or Control 1 (Control 1 and Sample B both having a peroxide curing agent). Sample A demonstrates lower qualitative porosity than Control 2 (Control 2 and Sample A both being cured with a bisphenol curing agent). Sample C, being uncured and essentially non-porous, indicates an especially good permeation constant. For the blended samples, tests are conducted at a 2:1 ratio of fluoroelastomer to thermoplastic—a rough midpoint in the weight percentages where a dispersion of a fluoroelastomeric amorphous phase in a thermoplastic continuous phase occurs. The techniques of intermixing and dynamic vulcanization generate fluoroelastomeric amorphous particle sizes in the 0.1 micron to 100 microns range. Respective to the presumed relationship between porosity and fuel permeability, the porosity should improve as the thermoplastic phase is increased in relative proportion to the fluoroelastomeric amorphous phase to the 30 weight percent amount for the fluoroelastomeric amorphous phase (below which level the amount of fluoroelastomer imparts substantially diminished fluoroelastomer character to an FKM-TPV or FKM-gum/thermoplastic blend). The porosity should continue to be low in the FKM-TPVs and in the FKM-gum/thermoplastic blend as the fluoroelastomeric amorphous phase is increased in relative proportion to the thermoplastic phase to the 85 weight percent amount of the fluoroelastomeric amorphous phase for FKM-TPVs or to the 95 weight percent amount for FKM-gum/thermoplastic blends (above which levels the amount of thermoplastic imparts substantially diminished thermoplastic character to an FKM-TPV or FKM-gum/thermoplastic blend). The permeation constant of Sample A as compared to the Control 1 indicates that the porosity of a FKM-TPV cured by bisphenol at or above a 2:1 fluoroelastomer to thermoplastic ratio equals or approaches that of peroxide cured FKM rubber.

### Example 2

One hundred parts by weight of fluoroelastomer gum (FKM TFE/HFP/VdF terpolymer gum from Unimatec as Noxtite™ RE-351) are blended with fifty parts by weight of ETFE thermoplastic (ethylene-tetrafluoroethylene copolymer from Dyneon as ET-2635) and with 15 parts by weight of electrically conductive Sterling C grade type of carbon black (Cabot Corporation) particulate at a temperature of 500 degrees Fahrenheit in a twin screw mixer for 5 minutes so that (a) the blended gum, thermoplastic, and conductive particulate are mixed to disperse the fluoroelastomer gum in the thermoplastic, (b) a multiphase fluoroelastomer gum and thermoplastic blend has been generated, and (c) the Sterling C carbon black particulate has been comprehensively dispersed. A mandrel of Hytrel™ polypropylene or nylon thermoplastic is extruded and cooled in a water bath in a vacuum sizing system to define the inner dimension of a desired tube. A (first) pultrusion is then performed using the mandrel as a pultrusion core component with the multiphase fluoroelastomer gum and thermoplastic blend being input from an extruder as a first feed stream into a (first) pultrusion die (at 500 degrees Fahrenheit) and with ETFE thermoplastic being extruded from a second extruder as a second feed stream into the pultrusion die. The pultrusion die and extruders are configured and operated to provide output from the pultrusion die of a 3-layer tube having the mandrel as an inner layer and 2 layers providing additional (beyond the wall thickness of the mandrel) wall thickness of about 0.005 inch with a 0.002 inch thick fluoropolymeric layer of the multiphase blend as a layer between the mandrel and an outer layer of the ETFE thermoplastic. The resultant 3-layer pultruded tube is air cooled to solidify the multiphase blend inner layer and the ETFE thermoplastic outer layer. A set of tubes having independent outside diameters of from about 0.25 inch to about 1.0 inch are made by the process. Each cooled tube (of the set) discharged from the pultrusion die is irradiated on the outer surface with a corona discharge to activate the surface of the ETFE layer and thereby promote adhesion between the ETFE layer and an eventual outside layer. The surface treated multilayer tube is then input as a pultrusion core component to a second pultrusion die. A third extruder feeds either Vamac™ AEM rubber or CPE (chlorinated polyethylene) rubber as a molten feed stream into the second pultrusion die. The pultrusion die and third extruder are configured and operated to provide output from the pultrusion die of 4-layer pultruded tubes in various nominal diameters of between about 0.5 inch and about 1.5 inch (depending, in part, upon the particular pultrusion core component size extruded from the coextrusion die). Each 4-layer pultruded tube is cooled in a cooling water bath to decrease the temperature of the outer layer to room temperature. The pultruded tubes are then placed in an autoclave at about 150 degrees Celsius for about 2 hours to cure the outside rubber layer and to shrink the Hytrel™ mandrel to a smaller diameter than the inside diameter defined by the internal diametric chord passing through the centerline of the tube and spanning the circumference defined by the inside surface of the fluoropolymeric layer. The shrunken mandrel is then removed from the 4-layer tube to provide a residual 3-layer tube having the fluoropolymeric layer as the inside layer, an outside rubber layer of either Vamac™ AEM rubber or CPE (chlorinated polyethylene) rubber (respective to the material fed through the third extruder), and an ETFE layer between the inside layer and the outside layer where the ETFE layer is cohered to the fluoropolymeric layer and also to the outside rubber layer.

Each residual 3-layer tube (having an AEM rubber outer layer or CPE rubber outer layer, an inside lining layer of the irradiated multiphase blend, and the irradiated ETFE layer disposed between the outer layer and the inside lining layer) is cut to provide cross-sectional profiles, and the thicknesses and layer thicknesses of the pultruded tube cross sections are measured on the profiles using calipers and a microscope. The measured layer thicknesses of the irradiated multiphase blend inner layers range from 1 to 3 mils. The measured layer thicknesses of the irradiated ETFE layers range from 3 to 5 mils.

### Example 3

A multilayer tube made according to the process of Example 2 and having an outside diameter of 13/16 inches and a length of 2 and 15/16 inches is filled with ASTM D814Fuel C gasoline, sealed at both ends, and stored at room temperature. The weight of the filled tube is measured over a period of days. Results of the measurements are indicated in Table 3.

TABLE 3
Weight change in a filled tube

| | | Cumulative change in weight from |
|---|---|---|
| Days | Weight (grams) | initial (stabilized) weight (grams) |
| 0 | 18.733 | 0.000 |
| 1 | 18.668 | 0.065 |
| 2 | 18.538 | 0.195 |
| 4 | 18.528 | 0.205 |
| 6 | 18.521 | 0.212 |
| 8 | 18.517 | 0.216 |
| 10 | 18.459 | 0.274 |
| 12 | 18.423 | 0.310 |
| 14 | 18.379 | 0.354 |
| 16 | 18.345 | 0.388 |
| 18 | 18.326 | 0.407 |

The above table demonstrates a permeability constant of about 0.02 gm-mm/m²/day respective to the inside lining thickness of the test sample in providing permeability resistance to the filled tube. This is comparable to the permeabilty constant derived in Example 1 for Sample C of 2 mm thickness FKM gum in thermoplastic.

### Example 4

A 3-layer multilayer tube is prepared according to the process of Example 2. A 2-layer multilayer tube of essentially identical external and thickness dimensions (to those of the 3-layer multilayer tube) is also prepared by first making a pultrusion core component mandrel according to the mandrel making portion of the process described in Example 2, pultruding and cooling a 2-layer tube having a layer of thickness of about 0.005 inch of ETFE thermoplastic on the mandrel, subsequently pultruding a 3-layer multilayer tube with an outside rubber layer substantially according to the second pultrusion portion of the process described in Example 2, and removing the mandrel according to the process described in Example 2. Two tubes of essentially identical external and wall thickness dimensions are thereby provided, with the first tube being a 3-layer multilayer tube having an inside lining derived from a multiphase fluoroelastomer gum and thermoplastic blend, and with the second tube being a 2-layer multilayer tube essentially identical to the 3-layer multilayer tube except for an inside lining of ETFE rather than an inside lining derived from a multiphase fluoroelastomer gum and thermoplastic blend. One end of the 3-layer multilayer tube is compressively fitted over an end of a metal tube in a first test for testing fuel loss from the 3-layer multilayer tube and its compressive fitting. One end of the 2-layer multilayer tube is compressively fitted over an end of a metal tube in a second test for testing fuel loss from the 2-layer multilayer tube and its compressive fitting. Both the first and second tests are performed at essentially identical conditions. Testing of the 3-layer multilayer tube and compressive fitting indicates a lifetime for useful retention of ASTM D814Fuel C gasoline that is up to tenfold the lifetime for useful retention of ASTM D814Fuel C gasoline respective to the 2-layer multilayer tube. These results also bring forth the consideration that overall fuel permeability is affected by both chemo-resistant properties of a polymeric tube as well as by compressive set properties of the polymeric tube in a system having a polymeric tube compressively fitted around one end of a metal tube, to a male hose adaptor, or to another such fitting. Compressive set is estimated to be a value of about 60 for the fluoropolymeric layer of the 3-layer tube.

The examples and other embodiments described herein are exemplary and not intended to be limiting in describing the full scope of compositions and methods of this invention. Equivalent changes, modifications and variations of specific embodiments, materials, compositions and methods may be made within the scope of the present invention, with substantially similar results.

What is claimed is:

1. A multilayer polymeric composite, comprising
at least one polymeric structural layer; and
a fluoropolymeric layer cohered to at least one said polymeric structural layer;
wherein the fluoropolymeric layer comprises a multiphase composition comprising:
a continuous phase comprising a thermoplastic polymer material, and
an amorphous phase dispersed in the continuous phase wherein the amorphous phase comprises fluoroelastomer.

2. A multilayer polymeric composite according to claim 1 wherein the thermoplastic polymer material is radiation crosslinked.

3. The multilayer polymeric composite of claim 1 wherein the fluoroelastomer is uncured.

4. The multilayer polymeric composite of claim 1 wherein the fluoroelastomer is cured.

5. The multilayer polymeric composite of claim 1 wherein the fluoroelastomer is cured by both a peroxide curing system and a phenolic curing system.

6. The multilayer polymeric composite of claim 1 wherein the amorphous phase comprises cured fluoroelastomeric amorphous phase portions having independent diameters of from about 0.1 microns to about 100 microns, the cured fluoroelastomeric amorphous phase portions comprise the fluoroelastomer, and the fluoroelastomer is from about 30 to about 85 weight percent of the fluoropolymeric layer.

7. The multilayer polymeric composite of claim 1 wherein the amorphous phase comprises uncured fluoroelastomeric amorphous phase portions having independent diameters of from about 0.1 microns to about 100 microns, the uncured fluoroelastomeric amorphous phase portions comprise the fluoroelastomer, and the fluoroelastomer is from about 30 to about 95 weight percent of the fluoropolymeric layer.

8. The multilayer polymeric composite of claim 1 wherein the multiphase composition is derived from mixing uncured fluoroelastomer into the thermoplastic to provide from about 30 to about 95 weight percent of uncured fluoroelastomer in the multiphase composition, and the multiphase composition is a co-continuous polymer matrix multiphase composition wherein the amorphous phase has a maximum cross-sectional diameter of from about 0.1 microns to about 100 microns.

9. A multilayer polymeric composite according to claim 8 wherein the thermoplastic polymer material is radiation crosslinked.

10. The multilayer polymeric composite of claim 1 wherein the thermoplastic polymer material comprises a fluoroplastic.

11. The multilayer polymeric composite of claim 1 having a permeation constant of not greater than 25 gms-mm/m²/day to ASTM D814 Fuel C gasoline.

12. The multilayer polymeric composite of claim 1 wherein the fluoropolymeric layer is cohered to the polymeric structural layer with an adhesive layer.

13. The multilayer polymeric composite of claim 11 wherein the multilayer polymeric composite is configured to be a fuel hose, the polymeric structural layer is an outer layer of the fuel hose, the fluoropolymeric layer further comprises a dispersed phase of conductive particulate such that the fluoropolymeric layer has an electrical resistivity of less than about 1×10⁻³ Ohm-m at 20 degrees Celsius, and the fluoropolymeric layer is cohered to the outer layer to provide an electrically conductive inner lining of the fuel hose.

14. The multilayer polymeric composite of claim 1 wherein the fluoropolymeric layer further comprises filler.

15. The multilayer polymeric composite of claim 1 wherein the multilayer polymeric composite is configured to be a tubular conduit, and the polymeric structural layer is an outer layer of the tubular conduit.

16. The multilayer polymeric composite of claim 1 wherein the polymeric structural layer is encapsulated by the fluoropolymeric layer to provide a core in the multilayer polymeric composite.

17. The multilayer polymeric composite of claim 1 having a compression set value not greater than 60.

18. The multilayer polymeric composite of claim 1 wherein the fluoropolymeric layer has a layer thickness of from about 0.5 mil to about 10 mils.

19. The multilayer polymeric composite of claim 1 wherein the fluoropolymeric layer has a layer thickness, the multilayer polymeric composite has a composite thickness, and the ratio of the layer thickness to the composite thickness is from about 1:25 to about 1:250.

20. The multilayer polymeric composite of claim 1, wherein:
a first polymeric structural layer provides a first outside layer for the multilayer polymeric composite,
a second polymeric structural layer provides a second outside layer for the multilayer polymeric composite,
the fluoropolymeric layer is an internal layer in the multilayer polymeric composite, and
the first outside layer and the second outside layer independently cohere to the internal layer.

21. The multilayer polymeric composite of claim 20 wherein the fluoropolymeric layer is cohered to the first outside layer with a first adhesive layer, and the fluoropolymeric layer is cohered to the second outside layer with a second adhesive layer.

22. The multilayer polymeric composite of claim 1, wherein the fluoropolymeric layer is encapsulated within a polymeric structural layer to provide an elastomeric core in the multilayer polymeric composite.

23. The multilayer polymeric composite of claim 1 wherein the multilayer polymeric composite is configured to be a packing sealant article selected from the group consisting of a gasket, a dynamic seal, a static seal, and an o-ring.

24. The multilayer polymeric composite of claim 1 wherein the multilayer polymeric composite is configured to be any of a pump diaphragm and a peristaltic pump flexure tube.

25. An o-ring according to claim 1.

26. A seal according to claim 1.

27. A gasket according to claim 1.

28. A method for forming a multilayer polymeric composite, comprising:
cohering a fluoropolymeric layer to a polymeric structural layer to form the multilayer polymeric composite;
wherein the fluoropolymeric layer comprises a multiphase composition comprising:
a continuous phase comprising a thermoplastic polymer material, and
an amorphous phase dispersed in the continuous phase wherein the amorphous phase comprises fluoroelastomer.

29. The method of claim 28 further comprising irradiating the multilayer polymeric composite.

30. The method of claim 29 wherein the irradiating comprises exposing the multilayer polymeric composite to electron beam radiation of from about 0.1 MeRAD to about 40 MeRAD.

31. The method of claim 28 wherein the fluoroelastomer of the amorphous phase comprises cured fluoroelastomer.

32. The method of claim 28 wherein the fluoroelastomer of the amorphous phase comprises uncured fluoroelastomer.

33. The method of claim 28 wherein the cohering comprises any of pultrusion, compression molding, multi-layer extrusion, co-extrusion, injection molding, transfer molding, and insert molding.

34. The method of claim 28 wherein the cohering further comprises:
making a mandrel;
pultruding the fluoropolymeric layer and the polymeric structural layer onto the mandrel; and
removing the mandrel such that the multilayer polymeric composite is a residual of the pultruding and removing.

35. The method of claim 34 wherein the amorphous phase comprises uncured fluoroelastomer and the fluoropolymeric layer has a thickness of not greater than 3 mils.

36. The method of claim 35 wherein the cohering further comprises irradiation of the uncured fluoroelastomer after removing the mandrel.

37. A multilayer polymeric composite article made by a process according to the method of claim 28.
